(19) United States
(12) Patent Application Publication
(10) Pub. No.: US 2025/0237228 A1
(43) Pub. Date: Jul. 24, 2025

(54) FAN-SPEED CONTROL DEVICE HAVING A CAPACITIVE TOUCH SURFACE

(71) Applicant: Lutron Technology Company LLC, Coopersburg, PA (US)

(72) Inventors: Gregory S. Altonen, Easton, PA (US); Damien N. Bobrek, Boynton Beach, FL (US); Chris Dimberg, Easton, PA (US); Bryce C. Herrera, Wellington, FL (US); Jason C. Killo, Emmaus, PA (US); Adam Rosenberg, Wellington, FL (US); Daniel L. Twaddell, Bethlehem, PA (US); Aaron J. Wilz, Emmaus, PA (US); Edward Wunsch, Quakertown, PA (US)

(73) Assignee: Lutron Technology Company LLC, Coopersburg, PA (US)

(21) Appl. No.: 19/035,716

(22) Filed: Jan. 23, 2025

Related U.S. Application Data
(60) Provisional application No. 63/624,078, filed on Jan. 23, 2024.

(51) Int. Cl. F04D 27/00; F04D 25/08; H03K 17/18; H03K 17/96

(52) U.S. Cl. CPC F04D 27/004; H03K 17/18; H03K 17/962; F04D 25/088

(57) ABSTRACT

A control device for controlling a motor load may comprise an actuation member having a front surface defining a touch sensitive surface configured to detect a touch actuation along at least a portion of the touch sensitive surface, and a light bar configured to be illuminated to indicate a rotational speed of the motor load. The control device may also comprise a control circuit configured to determine control data for adjusting a rotational speed of the motor load to one of a number of discrete speeds in response to which of a number of respective regions along the light bar on the touch sensitive surface in which the touch actuation occurs. The control circuit may illuminate a portion of the light bar to indicate the one of the number of discrete speeds to which the rotational speed of the motor load is controlled in response to the control data.

### CROSS-REFERENCE TO RELATED APPLICATIONS

This application claims the benefit of Provisional U.S. Patent Application No. 63/624,078, filed Jan. 23, 2024, the entire disclosures of which are hereby incorporated by reference herein in their entirety.

### BACKGROUND

A user environment, such as a residence or an office building for example, may be configured using various types of load control systems. A lighting control system may be used to control the lighting loads in the user environment. A motorized window treatment control system may be used to control the natural light provided to the user environment. A heating, ventilation, and air-conditioning (HVAC) system may be used to control the temperature in the user environment. Each load control system may include various control devices, including control-source devices and control-target devices. The control-target devices may receive digital messages, which may include load control instructions, for controlling an electrical load from one or more of the control-source devices. The control-target devices may be capable of directly controlling an electrical load. The control-source devices may be capable of indirectly controlling the electrical load via the control-target device. Examples of control-target devices may include lighting control devices (e.g., a dimmer switch, an electronic switch, a ballast, or a light-emitting diode (LED) driver), a motor control device (e.g., for a ceiling fan or exhaust fan), a motorized window treatment, a temperature control device (e.g., a thermostat), an AC plug-in load control device, and/or the like. Examples of control-source devices may include remote-control devices, occupancy sensors, daylight sensors, temperature sensors, and/or the like.

### SUMMARY

As described herein, a control device for controlling a motor load may comprise an actuation member having a front surface defining a touch sensitive surface configured along at least a portion of the touch sensitive surface, and a light bar (e.g., a continuous light bar) configured to be illuminated by a plurality of light sources to indicate a rotational speed of the motor load. The control device may also comprise a control circuit configured to determine control data for controlling the motor load in response to actuations of the actuation member. The control circuit may be configured to determine first control data for turning the motor load on in response to an actuation of an upper portion of the actuation member, and second control data for turning the motor load off in response to an actuation of a lower portion of the actuation member. The control circuit may be further configured to determine that a touch actuation occurs along the touch sensitive surface and to determine third control data for adjusting a rotational speed of the motor load to one of a number of discrete speeds in response to which of a number of respective regions along the light bar on the touch sensitive surface in which the touch actuation occurs. When the motor load is on, the control circuit may be configured to illuminate a portion of the light bar to indicate the one of the number of discrete speeds to which the rotational speed of the motor load is controlled in response to the third control data.

In some examples, the control circuit may be configured to control the rotational speed of the motor load to four discrete speeds, and the regions along the light bar may comprise a first region, a second region, a third region, and a fourth region. The first, second, third, and fourth regions may each comprise a respective length along the light bar. The first region may be located at the bottom end of the light bar, the second region may be located above the first region, the third region may be located above the second region, and the fourth region may be located above the third region. The control circuit may be configured to control the motor load to a first speed in response to an actuation of the touch sensitive surface within the first region along the light bar, to a second speed in response to an actuation of the touch sensitive surface within the second region along the light bar, to a third speed in response to an actuation of the touch sensitive surface within the third region along the light bar, and to a fourth speed in response to an actuation of the touch sensitive surface within the fourth region along the light bar. The lengths of the first and fourth regions may each be less than each of the lengths of the second and third regions. The lengths of the first and fourth regions may be equal to each other, and the lengths of the second and third regions may be equal to each other, such that the second and third regions meet at a midpoint of the actuation member and/or the light bar.

The light bar may include a continuous light bar. The control circuit may be configured to illuminate a first portion of the light bar when the motor load is controlled to the first speed, a second portion of the light bar when the motor load is controlled to the second speed, a third portion of the light bar when the motor load is controlled to the third speed, and/or a fourth portion of the light bar when the motor load is controlled to the fourth speed. In some examples, the first portion extends from the bottom end to a first point on the light bar, the second portion extends from the bottom end to a second point on the light bar, the third portion extends from the bottom end to a third point on the light bar, and the fourth portion extends from the bottom end to a fourth point on the light bar. The second point may be at the midpoint of the light bar and the fourth point may be at the top end of the light bar. In some examples, the first portion extends for 25% of the length of the light bar, the second portion extends for 50% of the length of the light bar, the third portion extends for 75% of the length of the light bar, and the fourth portion extends for 100% of the length of the light bar. Further, in some examples, the first portion extends for a length equal to the length of the first region, the second portion extends for a length equal to the lengths of the first and second regions, the third portion extends for a length equal to the length of the first, second, and third regions, and the fourth portion extends for a length equal to the length of the first, second, third, and fourth regions. The first portion may extend into the second region, and the third portion may extend a distance into the third region that is less than the length of the third region.

In some examples, the lengths of first, second, third, and fourth portions are equal. For instance, each of the lengths of first, second, third, and fourth illuminated portions are equal to approximately 25% of the length of the light bar.

The first portion may extend from the bottom end to a first point on the light bar, the second portion may extend from the first point on the light bar to a second point on the light bar, the third portion may extend from the second point on the light bar to a third point on the light bar, and the fourth portion may extend from the third point on the light bar to a fourth point on the light bar. The second point may be at the midpoint of the light bar and the fourth point is at the top end of the light bar. Each of the first portion, second, portion, third portion, and forth portion may extend for a respective 25% of the length of the light bar. The first portion may extend for a length equal to the length of the first region, the second portion may extend for a length equal to the length of second region, the third portion may extend for a length equal to the length of third region, and the fourth portion may extend for a length equal to the length of the fourth region. In some examples, the first portion may extend into the second region, and the third portion may extend a distance into the third region that is less than the length of the third region.

The actuation member may include an upper portion and a lower portion. The actuation member may be configured to pivot about a pivot axis. The control circuit may be configured to determine the first control data for turning the motor load on in response to an actuation of the upper portion the actuation member, and to determine the second control data for turning the motor load off in response to an actuation of the lower portion of the actuation member. The actuation member may be configured to actuate a first tactile switch of the control device in response to a tactile actuation of the upper portion of the actuation member, and to actuate a second tactile switch of the control device in response to a tactile actuation of the lower portion of the actuation member. For example, the actuation member may be configured to actuate a push button of the control device, and the control circuit may be configured to determine the first control data for turning the motor load on in response to a first actuation of the actuation member, and to determine the second control data for turning the motor load off in response to a second actuation of the actuation member.

The control device may include a capacitive touch printed circuit board affixed to the actuation member, where for example, the capacitive touch printed circuit board may include one or more receiving capacitive touch pads located on the capacitive touch printed circuit board, and adjacent to a surface of the actuation member that is opposite the front surface, and arranged in a linear array adjacent to the touch sensitive surface. The control circuit may be responsive to inputs received from the capacitive touch pads of the capacitive touch printed circuit board. The capacitive touch printed circuit board may be configured to pivot with the actuation member in response to actuation of the upper portion and the lower portion of the actuation member.

In some examples, when the motor load is on, the control circuit is configured to determine fourth control data for adjusting the motor load to a maximum speed of the number of discrete speeds in response to an actuation of an upper portion of the actuation member.

The control device may include a motor load control circuit that is configured to conduct a load current through the motor load for controlling the rotational speed of the motor in response to the first, second, or third control data. The control device may include a communication circuit that is configured to transmit a message including the first, second, or third control data, wherein the message is configured to cause a change in the rotational speed of the motor. The light bar may be a continuous light bar. The touch sensitive surface may be positioned along and proximate to the light bar. The number of respective regions may be along the light bar on the touch sensitive surface.

The control circuit may be configured to control the rotational speed of the motor load to a plurality of discrete speeds, and the regions along the touch sensitive surface may include a plurality of regions, where each of the plurality of regions corresponding to a respective one of the plurality of discrete speeds. For example, the plurality of regions may each comprise a respective length along the touch sensitive surface, and wherein a second region of the plurality of regions is located above a first region of the plurality of regions. In some instances, the length of the first region may be shorter than the length of the second region. A third region of the plurality of regions may be located above the second region, and the lengths of the second and third regions may be equal to each other. The light bar may be a continuous light bar, and the control circuit may be configured to illuminate a first portion of the light bar when the motor load is controlled to a first of the plurality of discrete speeds, and a second portion of the light bar when the motor load is controlled to a second of the plurality of discrete speed. In such examples, the first portion may extend from the bottom end to a first point on the light bar, and the second portion may extend from the bottom end to a second point on the light bar. The plurality of regions may each define a respective length along the touch sensitive surface, and a second region of the plurality of regions may be located above a first region of the plurality of regions, and the length of the first region may be shorter than the length of the second region. For example, the first portion may extend for a length equal to the length of the first region, and the second portion may extend for a length equal to the lengths of the first and second regions. The first portion may extend into the second region. In some examples, lengths of first and second portions are equal. Further, in some instances, the first portion may extend from the bottom end to a first point on the light bar, and the second portion may extend from the first point on the light bar to a second point on the light bar. For instance, the first portion may extend for a length equal to the length of the first region, and the second portion may extend for a length equal to the length of second region. The first portion may extend into the second region.

### BRIEF DESCRIPTION OF THE DRAWINGS

FIG. 1 is a diagram of an example load control system for controlling the operation of an electrical device, such as a ceiling fan.

FIG. 2A is a perspective view of an example control device, such as a fan-speed control device for controlling a motor load, such as a motor of a ceiling fan.

FIG. 2B is a front view of the control device of FIG. 2A.

FIGS. 3A-3D are front views of a user interface of the control device of FIG. 2A that illustrate illumination on a light bar to indicate the first, second, third, or fourth speeds of the ceiling fan.

FIGS. 4A-4D are front views of a user interface of the control device of FIG. 2A that illustrate illumination on a light bar to indicate the first, second, third, or fourth speeds of the ceiling fan.

FIG. 5 is a partially exploded view of the control device of FIG. 2A.

FIG. 6A is a cross-sectional view of the control device of FIG. 2A taken through the center of the control device (e.g., through the line shown in FIG. 2B).

FIG. 6B is a side cross-sectional view of the control device of FIG. 2A taken through a center of an antenna printed circuit board (e.g., through the line shown in FIG. 2B).

FIG. 7 is a perspective view of a base portion of the control device of FIG. 2A.

FIG. 8 is a front view of the base portion of the control device of FIG. 2A.

FIG. 9 is a front view of the control device of FIG. 2A with an actuator removed.

FIG. 10 is a side view of an example antenna printed circuit board.

FIG. 11 shows a simplified block diagram of an example fan-speed control device that may be implemented as the fan-speed control device illustrated in FIG. 2A.

FIGS. 12 and 13 are example flowcharts of control procedures configured to be executed by a control circuit of a load control device, such as the control device illustrated in FIG. 2A.

### DETAILED DESCRIPTION

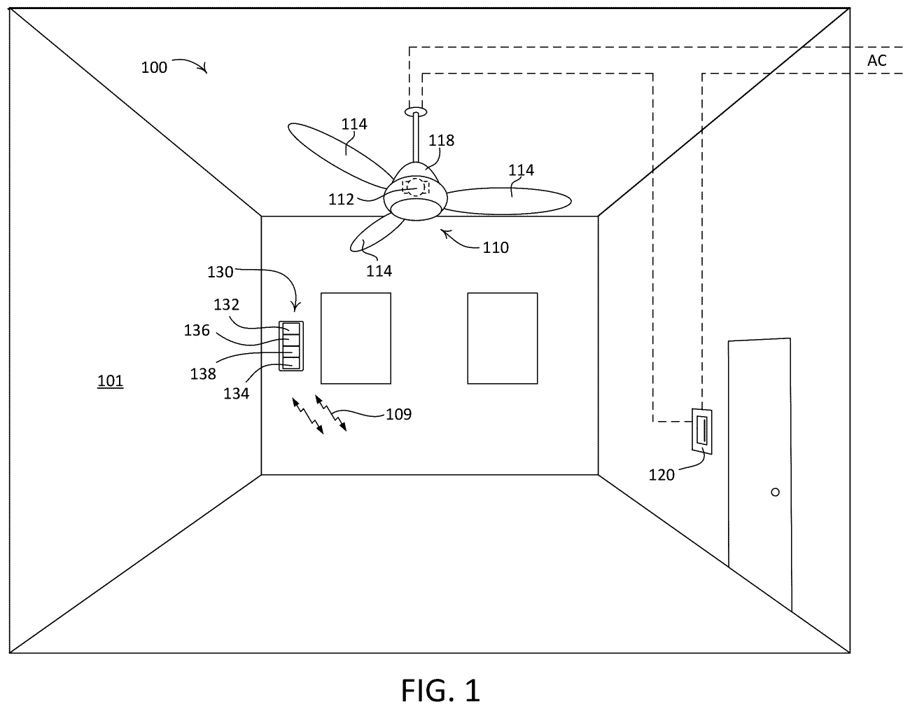

FIG. 1 is a diagram of an example load control system 100 for controlling the operation of an electrical device, such as a ceiling fan 110. The ceiling fan 110 may receive power from a power source, such as an alternating-current (AC) power source or a direct-current (DC) power source. The ceiling fan 110 may be installed on the ceiling of a room 101 or space in a building. The ceiling fan 110 may comprise a motor load, such as a motor 112 (e.g., a fan motor), for rotating a plurality of blades 114 (e.g., three blades as shown in FIG. 1) to circulate the air in the room 101. In some examples, the ceiling fan 110 may also include a control device or circuit that may be housed in a base portion 118 and may control the motor 112 (e.g., to turn on and off, adjust the rotational speed, and/or control the direction of rotation of the motor).

The load control system 100 may also comprise a load control device, such as a fan-speed control device 120 for controlling the motor 112 of the ceiling fan 110. The fan-speed control device 120 may be configured to be electrically coupled in series between the power source and the ceiling fan 110. For example, the fan-speed control device 120 may be configured to control a load current conducted through the motor 112 of the ceiling fan 110 to turn the motor of the ceiling fan 110 on and off and/or to adjust the rotational speed of the motor 112. The fan-speed control device 120 may comprise one or more actuators for receiving user inputs for controlling the motor 112 of the ceiling fan 110.

In addition, the fan-speed control device 120 may be configured to receive wired or wireless signals, such as radio-frequency (RF) signals 109, for controlling the motor 112 of the ceiling fan 110. The load control system 100 may comprise a remote control device 130 (e.g., a remote fan-speed control device) for transmitting messages (e.g., digital messages) including commands for controlling the motor 112 of the ceiling fan 110 via the RF signals 109. For example, the remote control device 130 may be battery-powered, and may be handheld, mounted to a wall, and/or mounted to a pedestal to be placed on a tabletop. The remote control device 130 may be configured to transmit the messages including commands for controlling the motor of the ceiling fan in response to actuations of a plurality of buttons, e.g., an on button 132, an off button 134, a raise-speed button 136, and a lower-speed button 138. The fan-speed control device 120 may be configured to turn on the ceiling fan 110 in response to actuations of the on button 132, and to turn off the ceiling fan 110 in response to actuations of the off button 134. The load control device may be configured to increase the rotational speed of the motor 112 of the ceiling fan 110 in response to actuations of the raise-speed button 136, and decrease the rotational speed of the motor 112 of the ceiling fan 110 in response to actuations of the lower-speed button 138. One will recognize that the control device of the ceiling fan 110 may also and/or alternatively be configured to receive control signals from a control device via a wired communication link.

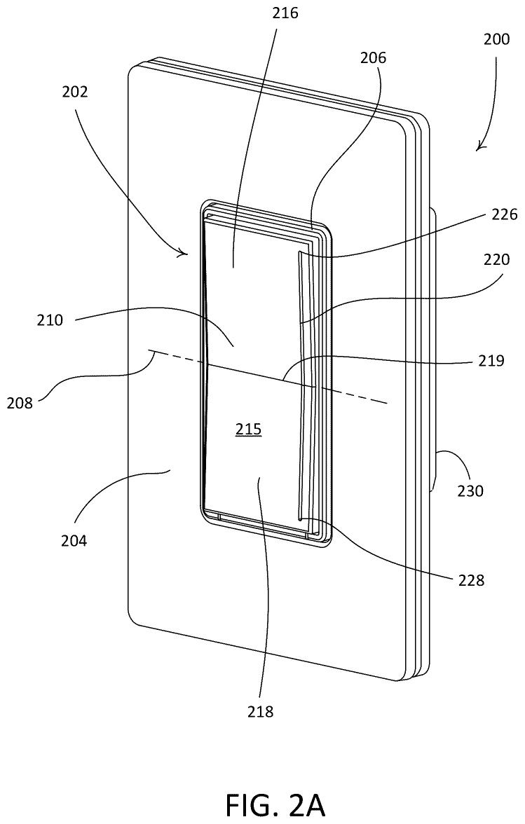

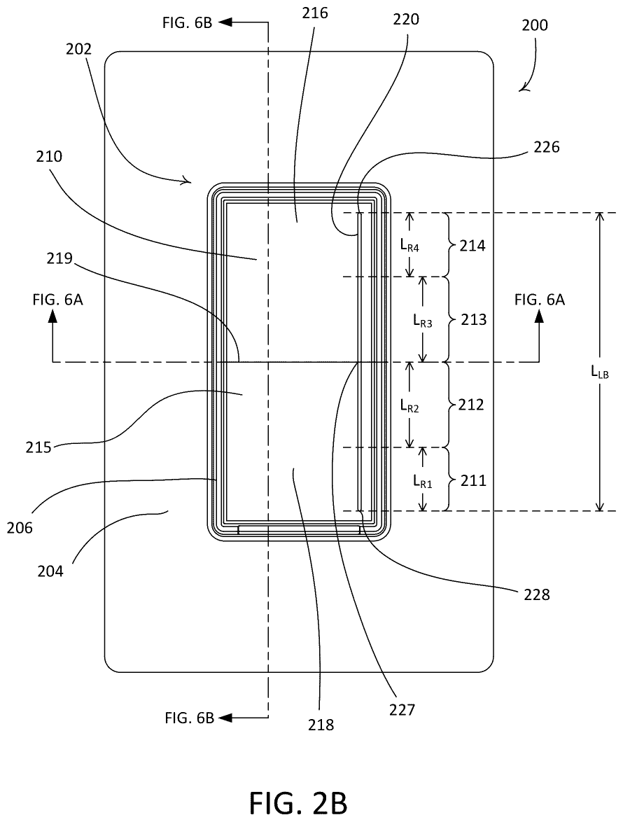

FIGS. 2A-9 depict an example fan-speed control device 200 for controlling a ceiling fan (e.g., the ceiling fan 110 shown in FIG. 1). FIG. 2A is a perspective view and FIG. 2B is a front view of the example fan-speed control device 200. The fan-speed control device 200 may comprise a user interface 202 and a faceplate 204. The fan-speed control device 200 may be configured to turn the motor of the ceiling fan on and off and/or to control a rotational speed ω_{fan} of the ceiling fan. For example, the fan-speed control device 200 may be configured to control the rotational speed ω_{fan} of the ceiling fan to a plurality discrete speeds (e.g., two discrete speeds, three discrete speeds, four discrete speeds, five discrete speeds, etc.), such as a first speed ω₁ (e.g., a minimum or low speed), a second speed ω₂ (e.g., a medium-low speed), a third speed ω₃ (e.g., a medium-high speed), and/or a fourth speed ω₄ (e.g., a maximum, high, or full-on speed). For description purposes, the fan-speed control device 200 will be described herein as having four discrete speeds. The fan-speed control device 200 may be configured to turn the motor of the ceiling fan on and off, and/or adjust the rotational speed ω_{fan} of the ceiling fan by controlling a magnitude of a load current conducted through a motor of the ceiling fan (e.g., the motor 112 of the ceiling fan 110) using an internal motor control circuit (e.g., the fan-speed control device 200 may be deployed as the first load control device 100 of the load control system 100). In addition, the fan-speed control device 200 may be configured to turn the motor of the ceiling fan on and off, and/or adjust the rotational speed ω_{fan} of the ceiling fan by transmitting, via a communication circuit (e.g., in a wireless signal via a wireless communication circuit) to the ceiling fan, a message including control instructions (e.g., one or more commands) for controlling the ceiling fan (e.g., the fan-speed control device 200 may be deployed as the remote control device 130 of the load control system 100). In such a configuration, the ceiling fan may include a communications interface and processor configured to receive such messages and in response, to control the rotational speed fan of the motor of the ceiling fan.

When the fan-speed control device 200 is a wall-mounted fan-speed control device, the fan-speed control device 200 may comprise a rear enclosure 230 for housing motor control circuitry of the fan-speed control device 200. For example, the rear enclosure 230 may enclose a portion (e.g., one or more components) of the fan-speed control device 200. The fan-speed control device 200 may be configured to be mounted to an electrical wallbox (e.g., a metal wallbox).

The user interface 202 of the fan-speed control device 200 may include an actuation member 210 that is configured to be mounted to a bezel 206 (e.g., a base portion). The actuation member 210 may comprise a front surface 215 including an upper portion 216 and a lower portion 218. The user interface 202 may include a light bar 220 extending along the length of the front surface 215 of the actuation member 210 for a length L_{LB} from a top end 226 to a bottom end 228. The light bar 220 may be configured to be illuminated by one or more light sources (e.g., one or more LEDs) to visibly display information. The actuation member 210 may be configured to pivot about a pivot axis 208 (e.g., a central axis) in response to a tactile actuation (e.g., a tactile input) of the upper portion 216 and the lower portion 218. The pivot axis 208 may be located near a center 219 of the actuation member 210. The fan-speed control device 200 may be configured to control the ceiling fan to turn the motor of the ceiling fan on in response to a tactile actuation of the upper portion 216, and to turn the motor of the ceiling fan off in response to a tactile actuation (e.g., a tactile input) of the lower portion 218 (or vice versa). For example, when the fan-speed control device 200 detects a tactile actuation of the upper portion 216 of the actuation member 210 and the ceiling fan is off, the fan-speed control device 200 may be configured to turn the motor of the ceiling fan on to a previous rotational speed (e.g., before the ceiling fan was previously turned off) or to a preset rotational speed (e.g., a predetermined or locked preset rotational speed). When the fan-speed control device 200 detects a tactile actuation of the upper portion 216 of the actuation member 210 and the ceiling fan is on, the fan-speed control device 200 may be configured to adjust the rotational speed ω_{fan} of the ceiling fan to the fourth speed ω₄ (e.g., the maximum, high, or full-on speed). The fan-speed control device 200 may include one or more tactile switches that are actuated in response to the tactile actuations of the upper and/or lower portions 216, 218 of the actuation member 210.

The fan-speed control device 200 may be configured to control the motor of the ceiling fan in response to a touch actuation of the actuation member 210. For example, the actuation member 210 may receive user inputs that do not cause the actuation member 210 to pivot (e.g., about the pivot axis 208). At least a portion of the front surface 215 of the actuation member 210 may be configured as a touch sensitive surface (e.g., a capacitive touch surface) through the use of a touch sensitive device that includes circuitry configured to receive (e.g., detect) inputs (e.g., touch actuations/inputs) on the touch sensitive surface, such as point actuations or gestures, from a user of the fan-speed control device 200. The touch sensitive surface of the actuation member 210 may be located adjacent to and/or overlap with the light bar 220, and may extend from approximately the top end 226 to the bottom end 228 of the light bar 220, although other configurations are possible (e.g., the touch sensitive surface may extend beyond the light bar at one or both the top end 226 and bottom end 228, the touch sensitive surface may not extend to the top end 226 and/or to the bottom end 228 of the light bar 220, etc.). In some examples, the touch sensitive surface of the actuation member 210 may be located along other areas of the front surface 215 of the actuation member 210 (e.g., not adjacent to the light bar). Examples of control devices having capacitive touch surfaces and/or touch sensitive devices are described in greater detail in commonly-assigned U.S. Pat. No. 10,109,181, issued Oct. 23, 2018, entitled GESTURE-BASED CONTROL DEVICE FOR CONTROLLING AN ELECTRICAL LOAD, and U.S. Pat. No. 11,569,818, issued Jan. 31, 2023, entitled LOAD CONTROL DEVICE HAVING A CAPACITIVE TOUCH SURFACE, the entire disclosures of which are hereby incorporated by reference. Although described primarily in context of a capacitive touch surface, it should be appreciated that the fan-speed control device 200 is not so limited, and in some examples, at least a portion of the front surface 215 of the actuation member 210 may be configured as a different type of touch sensitive surface, such as a resistive touch surface, an inductive touch surface, a surface acoustic wave (SAW) touch surface, an infrared touch surface, acoustic pulse touch surface, or the like.

The actuation member 210 may substantially maintain its position (e.g., with respect to the bezel 206) in response to touch actuations of the touch sensitive surface and, depending on the positions of the touch actuations, the fan-speed control device 200 may be configured to enter different operating modes and/or carry out different control functions in response. For example, during a normal operating mode, the fan-speed control device 200 may be configured to adjust the amount of power delivered to, and thus the rotational speed ω_{fan} of, the ceiling fan according to the position of the touch actuation on the front surface 215 of the actuation member 210 along the light bar 220 (e.g., along the touch sensitive surface). In addition, the fan-speed control device 200 may be configured to receive advanced touch actuations of the front surface 215 of the actuation member 210 along the light bar 220 (e.g., of the touch sensitive surface). The advanced touch actuations of the front surface 215 of the actuation member 210 may comprise, for example, a gesture (e.g., a swipe) or a press-and-hold actuation of the touch sensitive surface. For example, the fan-speed control device 200 may be configured to transmit a command to the ceiling fan to change the rotational direction of the ceiling fan in response to detecting a swipe of the light bar 220 in a first direction followed by a swipe of the light bar 220 in a second opposing direction in quick succession. In addition, the fan-speed control device 200 may be configured to change operating modes in response to detecting an advanced touch actuation. For example, the fan-speed control device 200 may be configured to change to a configuration mode in response to detecting a press-and-hold actuation of the touch sensitive surface at the center 219 of the light bar 220 (e.g., that does not cause the actuation member 210 to pivot).

The fan-speed control device 200 may be configured to control a rotational speed ω_{fan} of the ceiling fan to the plurality of discrete speeds based on the position of a touch actuation (e.g., a touch input) along the touch sensitive surface of the actuation member 210. For example, the fan-speed control device 200 may be configured to control the rotational speed ω_{fan} of the ceiling fan to one of the four discrete speeds ω₁-ω₄ depending upon which one of four regions (e.g., a first region 211, a second region 212, a third region 213, and a fourth region 214) of the touch sensitive surface on the actuation member 210 along the light bar 220 is actuated with the touch actuation. Each of the four regions of the touch sensitive surface may correspond to one of the respective four discrete speeds ω₁-ω₄. For example, the first region 211 may correspond to the first speed ω₁ (e.g., a minimum or low speed), the second region 212 may correspond to the second speed ω₂ (e.g., a medium-low speed), the third region 213 may correspond a third speed ω₃ (e.g., a medium-high speed), and the fourth region 214 may correspond to the fourth speed ω₄ (e.g., a maximum, high, or full-on speed). Again, one will appreciate the touch sensitive surface may include fewer than or more than four regions, depending on the number of discrete speeds the fan-speed control device 200 may be configured to control.

The first, second, third, and fourth regions 211-214 of the touch sensitive surface may each comprise a respective length along the light bar 220 (e.g., a respective length along the touch sensitive surface), where the first region 211 may be located at the bottom end 228 of the light bar 220, the second region 212 may be located above the first region 211, the third region 213 may be located above the second region 212, and the fourth region 214 may be located above the third region 213 (e.g., at the top end 226 of the light bar 220). The second region 212 and the third region 213 may meet at a midpoint 227 of the light bar 220 and/or at the center 219 of the actuation member 210. The fan-speed control device 200 may be configured to control the rotational speed ω_{fan} of the ceiling fan to the first speed ω₁ in response to a touch actuation of the actuation member 210 in the first region 211 along the light bar 220. The fan-speed control device 200 may be configured to control the rotational speed ω_{fan} of the ceiling fan to the second speed ω2 in response to a touch actuation of the actuation member 210 in the second region 212 along the light bar 220. The fan-speed control device 200 may be configured to control the rotational speed ω_{fan} of the ceiling fan to the third speed ω3 in response to a touch actuation of the actuation member 210 in the third region 213 along the light bar 220. The fan-speed control device 200 may be configured to control the rotational speed ω_{fan} of the ceiling fan to the fourth speed ω₄ in response to a touch actuation of the actuation member 210 in the fourth region 214 along the light bar 220.

The touch sensitive surface of the actuation member 210 may extend from approximately the top end 226 to the bottom end 228 of the light bar 220 (e.g., adjacent to and/or overlapping with the light bar 220). The first region 211 may extend from approximately the bottom end 228 of the light bar 220 for a length L_{R1} along light bar 220. The second region 212 may extend from the first region 211 for a length L_{R2} along the light bar 220 to the midpoint 227 of the light bar 220 (e.g., which may be located at the center 219 of the actuation member 210). The third region 213 may extend from the second region 212 (e.g., from the midpoint 227 of the light bar 220) for a length L_{R3} along the light bar 220. The fourth region 214 may extend from the third region 213 for a length L_{R4} along the light bar 220 (e.g., to the top end 226 of the light bar 220). The first, second, third, and fourth regions 211-214 may not overlap (e.g., as shown in FIG. 2B).

While the touch sensitive surface of the actuation member 210 may be split into four regions, the lengths L_{R1}, L_{R2}, L_{R3}, L_{R4} of the regions 211-214 may not be equal. For example, the lengths L_{R1}, L_{R4} of the regions 211, 214 near the top end 226 and the bottom end 228 of the light bar 220, respectively, may each be shorter than each of the lengths L_{R2}, L_{R3} of the regions 212, 213 towards the midpoint 227 of the light bar 220. In addition, the length L_{R1} of the first region 211 may be the same as the length L_{R4} of the fourth region 214, which may be equal to approximately 20% of the length L_{LB} of the light bar 220. Further, the length L_{R2} of the second region 212 may be the same as the length L_{R3} of the third region 213, which may be equal to approximately 30% of the length L_{LB} of the light bar 220. When applying a touch actuation to the touch sensitive surface along the light bar 220 to select the first speed ω1, the user of the fan-speed control device 200 may have a tendency to actuate the touch sensitive surface near the bottom end 228 of the light bar 220. Similarly, when applying a touch actuation to the touch sensitive surface along the light bar 220 to select the fourth speed ω₄, the user of the fan-speed control device 200 may be accustomed to actuating the touch sensitive surface near the top end 226 of the light bar 220. Because of the user's tendency to actuate the touch sensitive surface near the bottom end 228 and the top end 226 of the light bar 220 to select the first speed ω₁ and the fourth speed ω4, respectively, the lengths L_{R2}, L_{R3} of the regions 212, 213 towards the midpoint 227 of the light bar 220 may be sized to be greater than the lengths L_{R1}, L_{R4} of the regions 211, 214 near the top end 226 and the bottom end 228 of the light bar 220 to allow the user more room to locate their finger to select the second speed ω2 or the third speed ω₃.

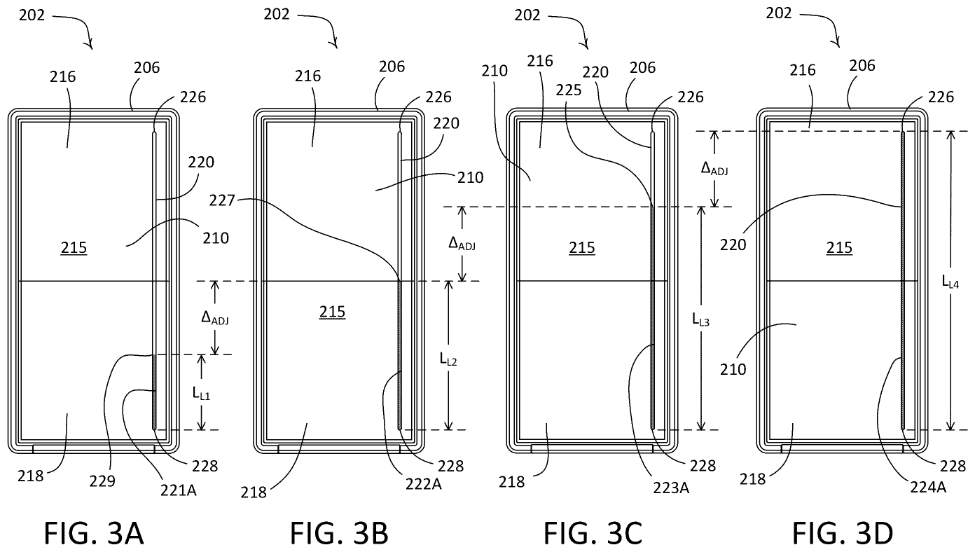

The fan-speed control device 200 may be configured to control the one or more light sources to illuminate the light bar 220 to indicate which of the first, second, third, or fourth speeds ω₁-ω₄ that the fan-speed control device 200 is presently controlling the ceiling fan. FIGS. 3A-3D are front views of the user interface 202 of the fan-speed control device 200 that illustrate illumination on the light bar 220 to indicate the first, second, third, or fourth speeds ω₁-ω₄, respectively. As shown in FIGS. 3A-3D, when the fan-speed control device 200 changes the rotational speed ω_{fan} of the ceiling fan from one speed to the next higher or lower speed, the fan-speed control device 200 may be configured to adjust an illuminated portion of the light bar 220 by an adjustment amount Δ_{ADJ}, which may be approximately 25% of the length L_{LB} of the light bar 220.

When the fan-speed control device 200 is controlling the rotational speed ω_{fan} of the ceiling fan to the first speed ω₁ (e.g., the minimum or low speed), the fan-speed control device 200 may be configured to illuminate a first illuminated portion 221A of the light bar 220 that extends from the bottom end 228 of the light bar 220 to a first point (e.g., a point 229) for a first length L_{L1} along the light bar 220. For example, the first length L_{L1} may be approximately 25% of the length L_{LB} of the light bar 220. When the fan-speed control device 200 is controlling the rotational speed ω_{fan} of the ceiling fan to the second speed ω₂ (e.g., the medium-low speed), the fan-speed control device 200 may be configured to illuminate a second illuminated portion 222A of the light bar 220 that extends from the bottom end 228 to a second point (e.g., the midpoint 227 of the light bar 220) for a second length L_{L2} along the light bar 220. For example, the second length L_{L2} may be approximately 50% of the length L_{LB} of the light bar 220. When the fan-speed control device 200 is controlling the rotational speed ω_{fan} of the ceiling fan to the third speed ω₃ (e.g., the medium-high speed), the fan-speed control device 200 may be configured to illuminate a third illuminated portion 223A of the light bar 220 that extends from the bottom end 228 of the light bar 220 to a third point (e.g., a point 225) for a third length L_{L3} along the light bar 220. For example, the third length L_{L3} may be approximately 75% of the length L_{LB} of the light bar 220. When the fan-speed control device 200 is controlling the rotational speed fan of the ceiling fan to the fourth speed ω₄ (e.g., the maximum or high speed), the fan-speed control device 200 may be configured to illuminate a fourth illuminated portion 224A of the light bar 220 that extends from the bottom end 228 to a fourth point (e.g., the top end 226 of the light bar 220) for a fourth length L_{LA} along the light bar 220. For example, the fourth length L_{L4} may be approximately 100% of the length L_{LB} of the light bar 220 (e.g., the fourth length L_{LA} may be equal to the length L_{LB} of the light bar 220). One will appreciate that if the fan-speed control device 200 is configured to control a ceiling fan to more or less than four discrete speeds ω₁-ω₄, the fan-speed control device 220 may be configured to adjust an illuminated portion of the light bar 220 by an adjustment amount Δ_{ADJ}, which may be less than or more than 25%, respectively.

In some examples, the fan-speed control device 200 may be configured to control the one or more light sources to illuminate the light bar 220, such that the illuminated portions of the light bar 220 extend to points that corresponds to the limits of the regions 211-214. For example, when the fan-speed control device 200 is controlling the rotational speed ω_{fan} of the ceiling fan to the first speed ω₁, the fan-speed control device 200 may be configured to illuminate the light bar 220, such that the illuminated portion extends along the light bar 220 from the bottom end 228 of the light bar 220 for the length L_{R1} of the first region 211. When the fan-speed control device 200 is controlling the rotational speed ω_{fan} of the ceiling fan to the second speed ω₂, the fan-speed control device 200 may be configured to illuminate the light bar 220, such that the illuminated portion extends along the light bar 220 from the bottom end 228 of the light bar 220 for the length L_{R1} of the first region 211 plus the length L_{R2} of the second region 212 (e.g., which may be equal to the second length L_{L2}). When the fan-speed control device 200 is controlling the rotational speed ω_{fan} of the ceiling fan to the third speed ω₃, the fan-speed control device 200 may be configured to illuminate the light bar 220, such that the illuminated portion extends along the light bar 220 from the bottom end 228 of the light bar 220 for the length L_{R1} of the first region 211 plus the length L_{R2} of the second region 212 and the length L_{R3} of the third region 213. When the fan-speed control device 200 is controlling the rotational speed ω_{fan} of the ceiling fan to the fourth speed ω₄, the fan-speed control device 200 may be configured to illuminate the light bar 220, such that the illuminated portion extends along the light bar 220 from the bottom end 228 of the light bar 220 for the length L_{R1} of the first region 211 plus the length L_{R2} of the second region 212 and the length L_{R3} of the third region 213 and the length L_{R4} of the fourth region 214. When the light bar 220 is illuminated in this manner, the fan-speed control device 200 may be configured to adjust the illuminated portion of the light bar 220 by different (e.g., unequal amounts) each time that the fan-speed control device 200 changes the rotational speed ω_{fan} of the ceiling fan from one speed to the next higher or lower speed.

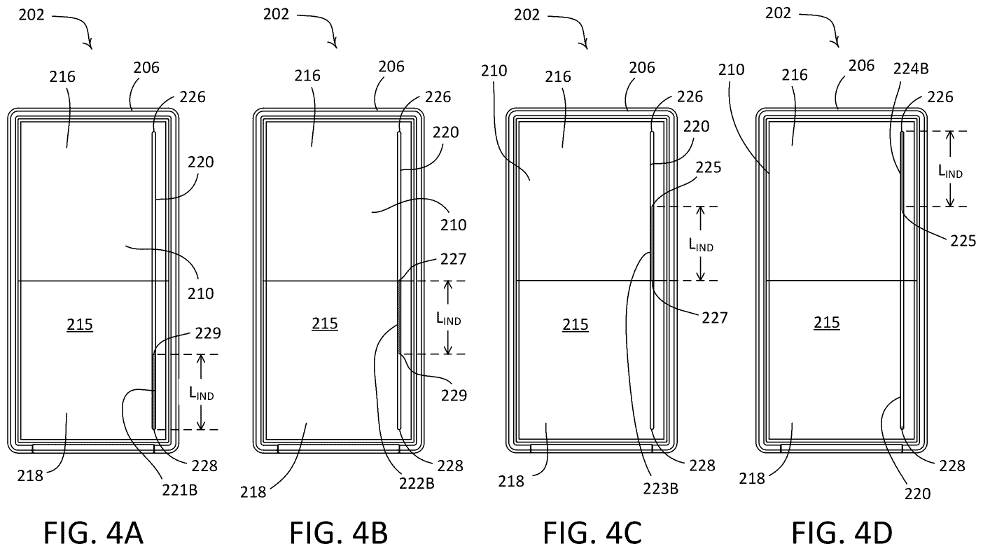

In addition, the fan-speed control device 200 may be configured to control the one or more light sources to illuminate the light bar 220, such that the lengths of the illuminated portions of the light bar 220 are each an indication length LIND. FIGS. 4A-4D are front views of the user interface 202 of the fan-speed control device 200 that illustrate illumination on the light bar 220 to indicate the first, second, third, or fourth speeds ω₁-ω₄, respectively, when the lengths of the illuminated portions of the light bar 220 are each the indication length LIND. For example, the indication length LIND may be approximately 25% of the length L_{LB} of the light bar 220 (e.g., when there are four discrete speeds). When the fan-speed control device 200 is controlling the rotational speed ω_{fan} of the ceiling fan to the first speed ω₁ (e.g., the minimum or low speed), the fan-speed control device 200 may be configured to illuminate a first illuminated portion 221B of the light bar 220 that extends from the bottom end 228 of the light bar 220 for the indication length LIND along the light bar 220 to the point 229. When the fan-speed control device 200 is controlling the rotational speed ω_{fan} of the ceiling fan to the second speed ω₂ (e.g., the medium-low speed), the fan-speed control device 200 may be configured to illuminate (e.g., only illuminate) a second illuminated portion 222B of the light bar 220 that extends from the point 229 for the indication length LIND along the light bar 220 to the midpoint 227 (e.g., and not illuminate the first illuminated portion 221B). When the fan-speed control device 200 is controlling the rotational speed ω_{fan} of the ceiling fan to the third speed ω₃ (e.g., the medium-high speed), the fan-speed control device 200 may be configured to illuminate (e.g., only illuminate) a third illuminated portion 223B of the light bar 220 that extends from the midpoint 227 for the indication length LIND along the light bar 220 of the light bar 220 to the point 225 (e.g., and not illuminate the first and second illuminated portions 221A, 221B). When the fan-speed control device 200 is controlling the rotational speed ω_{fan} of the ceiling fan to the fourth speed ω₄ (e.g., the maximum or high speed), the fan-speed control device 200 may be configured to illuminate (e.g., only illuminate) a fourth illuminated portion 224B of the light bar 220 that extends from the point 225 for the indication length LIND along the light bar 220 to the top end 226 (e.g., and not illuminate the first, second, nor third illuminated portions 221A, 221B, 221C). In some examples, the first, second, third, and fourth illuminated portions 221B-224B do not overlap (e.g., as shown in FIGS. 4A-4D). Additionally or alternatively, the first, second, third, and fourth illuminated portions 221B-224B may overlap slightly, e.g., due to dispersion of light shining through a diffuser of the fan-speed control device 200 (e.g., a diffuser 234 as will be described in greater detail below).

According to a further example, each of the first, second, third, and fourth illuminated portions 221A, 221B, 221C, 221D may not be of the same indication length LIND. For example, each of the first, second, third, and fourth illuminated portions 221A, 221B, 221C, 221D may correspond respectively in length to each of the first, second, third, and fourth regions 211-214 of the touch sensitive surface on the actuation member 210.

The fan-speed control device 200 may control the magnitude of the load current conducted through the motor of the ceiling fan based on a single discrete input along the touch sensitive surface and/or based on a plurality of consecutive inputs along the touch sensitive surface. For example, the user may tap their finger at a position along the touch sensitive surface, and in response, the fan-speed control device 200 may turn the motor of the ceiling fan on to a rotational speed based on the position of a touch actuation along the touch sensitive surface (e.g., to one of the first, second, third, or fourth speeds ω₁-ω₄ depending upon which of the first, second, third, or fourth regions 211-214 on the actuation member 210 along the light bar 220 is actuated). As an example, if the ceiling fan is off, the fan-speed control device 200 may turn the motor of the ceiling fan on to a rotational speed based on the position of a touch actuation along the touch sensitive surface of the actuation member 210. While the ceiling fan is on, the user may move (e.g., slide) their finger along the touch sensitive surface, and in response, the fan-speed control device 200 may adjust the rotational speed of the ceiling fan to one of the first, second, third, or fourth speeds ω₁-ω₄ based on the user's finger moving between the regions 211-214 on the actuation member 210 along the light bar 220.

The fan-speed control device 200 may be configured to prioritize user inputs that cause the actuation member 210 to pivot over user inputs that do not cause the actuation member 210 to pivot, or vice versa. For example, when the ceiling fan is off and a user moves a finger close to the upper portion 216 of the actuation member 210 causing the fan-speed control device 200 to detect a touch actuation via the touch sensitive surface (e.g., along the light bar 220), the fan-speed control device 200 may be configured to temporarily delay responding to detection of the touch actuations received via the touch sensitive surface to see if a user is attempting to actuate (e.g., tactile actuate) the upper portion 216 of the actuation member 210 to turn on the ceiling fan. Accordingly, the fan-speed control device 200 may avoid turning on the ceiling fan to a rotational speed based on the position of the actuation along the light bar 220 (e.g., in response to the touch sensitive surface) if the user's finger happens to sweep past the light bar 220 (e.g., the touch sensitive surface) while actuating the upper portion 216 of the actuation member 210 or if the user's finger actuates the upper portion 216 of the actuation member 210 too close to the light bar 220. In addition, when the ceiling fan is on and a user moves a finger close to the lower portion 218 of the actuation member 210 and the fan-speed control device 200 detects a tactile actuation of the lower portion to turn the ceiling fan off, if the fan-speed control device 200 also detects a touch actuation via the touch sensitive surface shortly thereafter, the fan-speed control device 200 may be configured to temporarily ignore the touch actuations received via the touch sensitive surface after the tactile actuation of the lower portion 218. Accordingly, the fan-speed control device 200 may avoid turning on the ceiling fan again if the user's finger happens to sweep past the light bar 220 while moving away from the lower portion 218 of the actuation member 210.

The fan-speed control device 200 may, for example, be configured to prioritize inputs received in response to actuation of the actuation member 210 over the inputs received via the touch sensitive surface by ignoring inputs received via the touch sensitive surface when a tactile actuation of the actuation member 210 is received within a blanking period (e.g., a first blanking period or an after-touch blanking period) after an initial detection of a touch actuation received via the touch sensitive surface. For example, the blanking period may be approximately 200 milliseconds. The blanking period may occur after (e.g., in response to) a touch actuation (e.g., the initial detection of a touch actuation). That is, the fan-speed control device 200 may ignore touch actuations received via the touch sensitive surface when a touch actuation of the actuation member 210 is received within the blanking period (e.g., a touch actuation that begins during the blanking period). For instance, in some examples, the fan-speed control device 200 may start the blanking period (e.g., a timer) in response to receiving a touch actuation via the touch sensitive surface, and ignore touch actuations received via the touch sensitive surface during the blanking period if the fan-speed control device 200 receives a tactile touch actuation of the actuation member 210 during the blanking period (e.g., a touch actuation begins during the blanking period). This may avoid unintentional touch actuations along the touch sensitive surface. As such, the fan-speed control device 200 may prioritize user inputs that cause the actuation member 210 to pivot over user inputs that do not cause the actuation member 210 to pivot during the blanking period.

Further, even if a blanking period is implemented, the fan-speed control device 200 may be configured to respond to a quick “tap” along the touch sensitive surface. For instance, the fan-speed control device 200 may be configured to determine that a touch actuation is at a position on the touch sensitive surface for an amount of time that is shorter than the blanking period without a tactile actuation of the actuation member 210 being detected (e.g., a touch actuation starts and finishes before the end of the blanking period) and, in response, turn the ceiling fan on/set the ceiling fan to a rotational speed associated with the region 211-214 on the actuation member 210 along the light bar 220 in which the touch actuation occurred in response to the touch actuation. Accordingly, the fan-speed control device 200 may both implement the blanking period to avoid unintentional touch actuations along the touch sensitive surface and still respond quickly to intentional touch actuations along the touch sensitive surface.

The fan-speed control device 200 may be configured to turn the ceiling fan on in response to a touch actuation received via the touch sensitive surface even when implementing the blanking period. For example, the fan-speed control device 200 may be configured to receive a touch actuation via the touch sensitive surface at a position for an amount of time that is greater than the blanking period without a tactile actuation of the actuation member 210 being detected (e.g., a touch actuation begins during the blanking period and ends after the blanking period) and, in response, turn the ceiling fan on to a rotational speed associated with the region 211-214 on the actuation member 210 along the light bar 220 in which the touch actuation occurred. Further, the fan-speed control device 200 may adjust the length of a blanking period, for example, through a user input (e.g., a touch actuation and/or a tactile actuation) received while in the advanced programming mode. For instance, in some examples, the blanking period may be configured to be greater than one second (e.g., multiple seconds). In such examples, the fan-speed control device 200 may respond to a press-and-hold touch actuation along the light bar 220 by turning the ceiling fan on to a rotational speed associated with the region 211-214 on the actuation member 210 along the light bar 220 in which the press-and-hold actuation occurred.

The fan-speed control device 200 may be configured to temporarily ignore inputs received via the touch sensitive surface after a tactile actuation of the actuation member 210 that causes the ceiling fan to turn on or off. The fan-speed control device 200 may be configured in this manner to, for example, avoid mistakenly turning the ceiling fan back on and/or adjusting the power delivered to (e.g., the rotational speed of) the ceiling fan after a tactile actuation of the actuation member 210. For example, the fan-speed control device 200 may be configured to ignore inputs received via the touch sensitive surface during a blanking period (e.g., a second blanking period or after-tactile period) after detecting a tactile actuation of the actuation member to turn the ceiling fan on or off. For instance, in some examples, the fan-speed control device 200 may start the blanking period in response to turning on or off the ceiling fan and, during the blanking period, ignore inputs received via the touch sensitive surface during the blanking period. As such, through the use of the blanking period, the fan-speed control device 200 may be configured to avoid unintentional touch actuations along the touch sensitive surface after a tactile actuation of the actuation member 210. In sum, the fan-speed control device 200 may be configured with one or more blanking periods, such as a first blanking period that is used to avoid unintentional touch actuations after an initial detection of a touch actuation received via the touch sensitive surface and prior to tactile actuations of the actuation member 210 (e.g., a blanking period that occurs after (e.g., in response to) a touch actuation), and/or a second blanking period that is used to avoid unintentional touch actuations after tactile actuations of the actuation member 210 (e.g., a blanking period that occurs after (e.g., in response to) a tactile actuation).

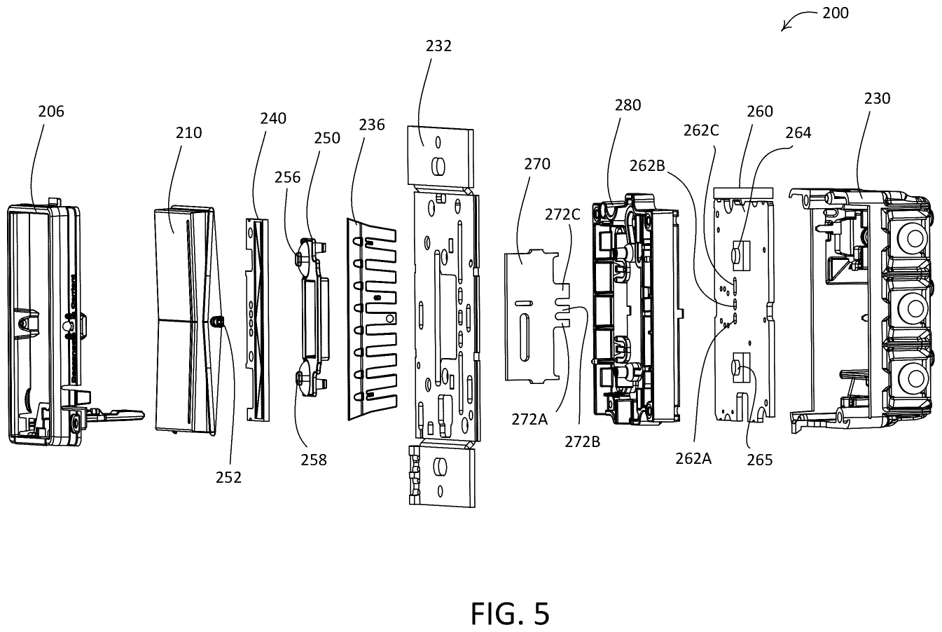

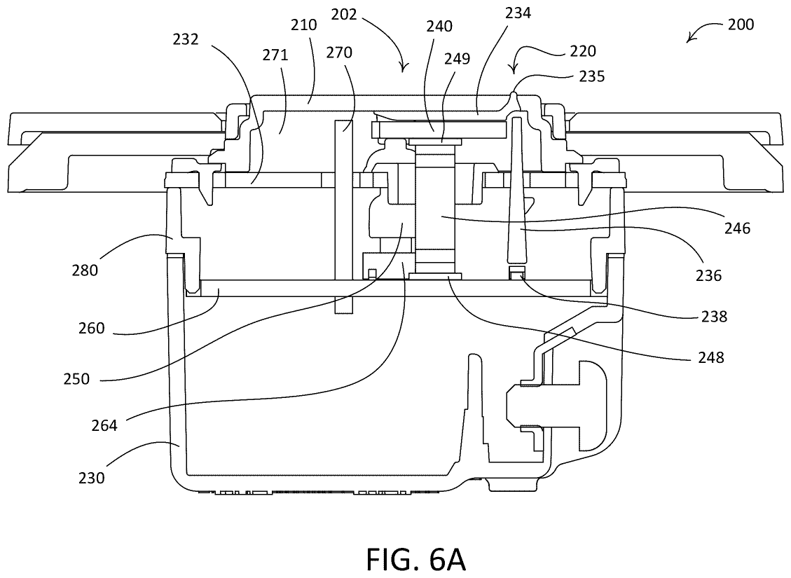

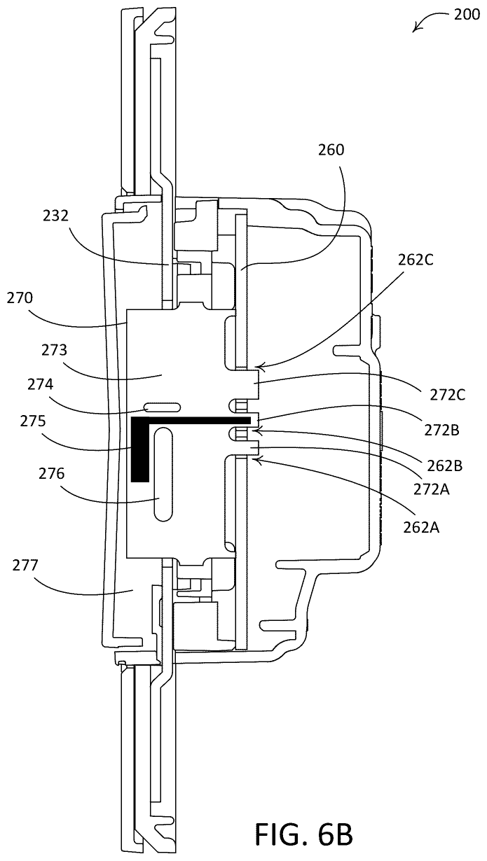

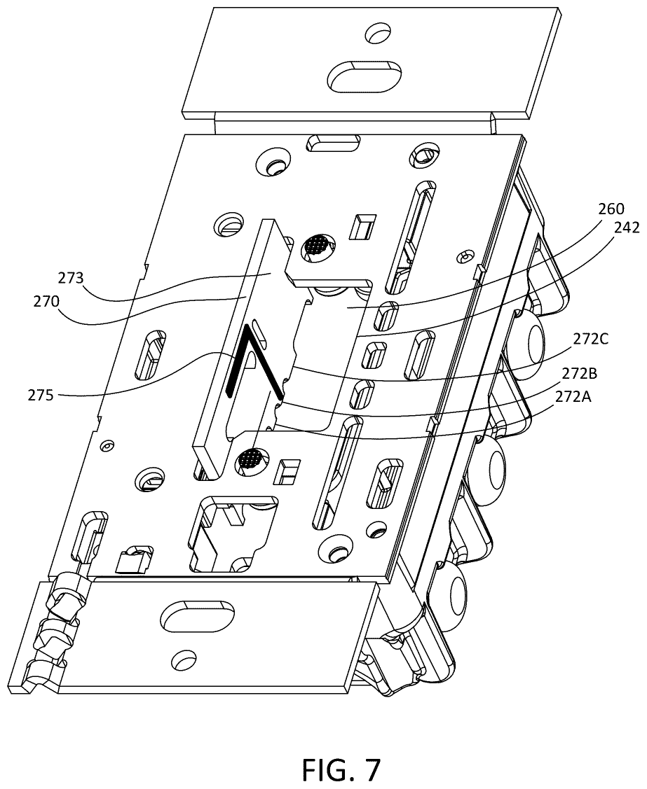

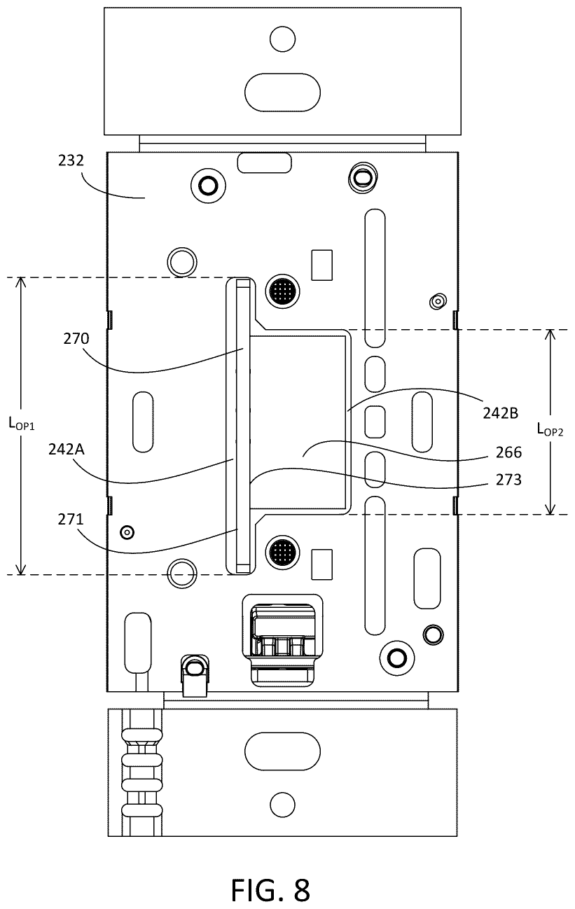

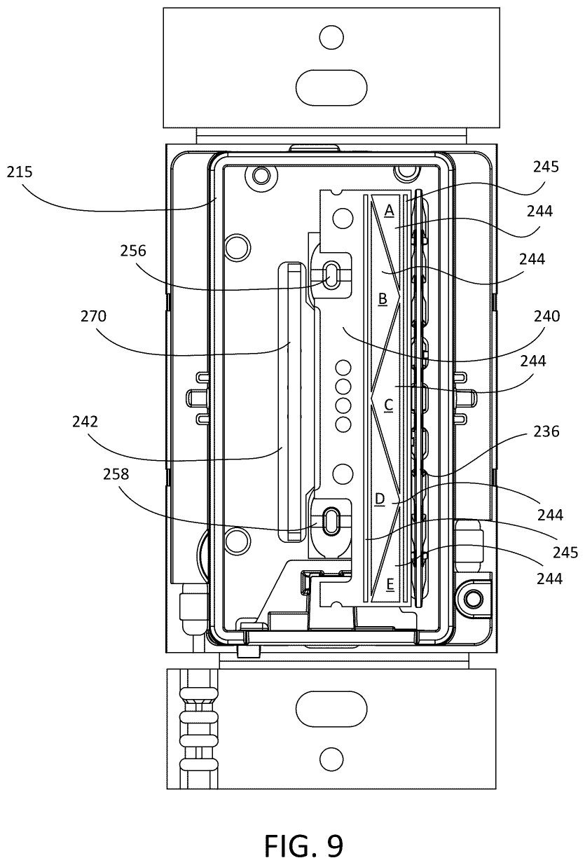

FIG. 5 is an exploded view of the fan-speed control device 200. The fan-speed control device 200 may include the actuation member 210, the bezel 206, an enclosure ring 280, a capacitive touch PCB 240, and a rear enclosure 230. FIG. 6A is a top cross-sectional view of the fan-speed control device 200 taken through the line shown in FIG. 2B. FIG. 6B is a right side cross-sectional view of the fan-speed control device 200 taken through the line shown in FIG. 2B. FIG. 7 is a perspective view of the fan-speed control device 200 with the bezel 206, the actuation member 210, and the capacitive touch PCB 240 removed. FIG. 8 is a front view of the fan-speed control device 200 with the bezel 206, the actuation member 210, and the capacitive touch PCB 240 removed. FIG. 9 is a front view of the fan-speed control device 200 with the actuation member 210 removed. As noted herein, the enclosure ring 280 and the rear enclosure 230 may together house the load control circuitry of the fan-speed control device 200. Although the fan-speed control device 200 is illustrated with the enclosure ring 280 and/or the rear enclosure 230, in some examples, such as when the fan-speed control device 200 is configured as or with a wireless, remote control device, the enclosure ring 280 and/or the rear enclosure 230 may be omitted. In some examples, the fan-speed control device 200 may connect to a base that is affixed to the toggle or paddle actuator of a standard light switch.

The fan-speed control device 200 may comprise a yoke 232 that may be configured to mount the fan-speed control device 200 to an electrical wallbox (e.g., when the fan-speed control device 200 is a wall-mounted dimmer switch). The yoke 232 may be connected to the rear enclosure 230, such that a main printed circuit board (PCB) 260 of the fan-speed control device 200 is located between the enclosure ring 280 and the rear enclosure 230. The yoke 232 may be a metal yoke and may be configured as a heat sink for the fan-speed control device 200. For example, the yoke 232 may include metal. As shown in FIG. 6A, the fan-speed control device 200 may comprise a diffuser 234 including a protruding portion 235 that extends through an elongated opening in the actuation member 210 to form the light bar 220. The fan-speed control device 200 may also comprise a light pipe 236 that may be configured to conduct light from one or more light sources 238 located inside of the rear enclosure 230 to the light bar 220. For example, the light sources 238 may comprise one or more light-emitting diodes (LEDs) mounted to the main PCB 260.

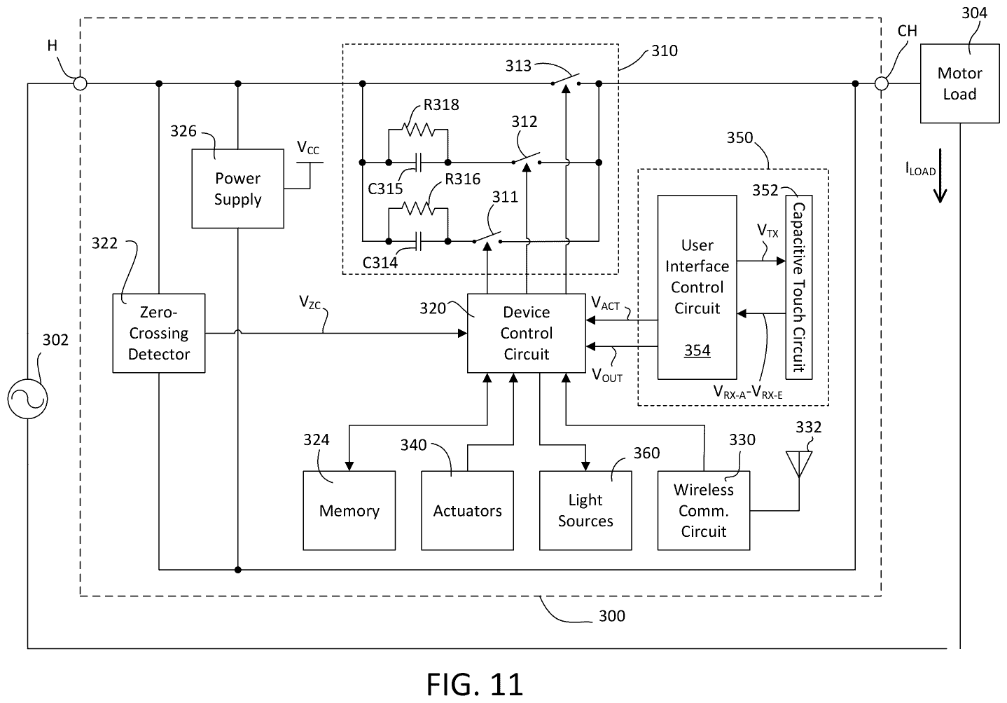

The main PCB 260 may be located within the rear enclosure 230. For example, the main PCB 260 may be attached to the rear enclosure 230 and/or the enclosure ring 280. The main PCB 260 may have mounted thereto the load control circuitry used to control power delivered to an electrical load. For example, the main PCB 260 may have mounted thereto any combination of a control circuit (e.g., a primary control circuit), memory, a drive circuit, one or more controllably conductive devices, a zero-crossing detector, a power supply, etc. (e.g., as shown in FIG. 11). The fan-speed control device 200 may also include mechanical switches, such as first and second tactile switches 264, 265, that may be mounted to the main PCB 260. The first and second tactile switches 264, 265 may be actuated in response to actuations (e.g., tactile actuations) of the upper portion 216 and the lower portion 218 of the actuation member 210, respectively (e.g., to control turning the load on and off). In some examples, the fan-speed control device 200 may be configured to control the ceiling fan to turn the motor of the ceiling fan on in response to an actuation of the first tactile switch 264 and to turn the motor of the ceiling fan off in response to an actuation of the second tactile switch 265.

The fan-speed control device 200 may also comprise a touch sensitive printed circuit board, such as a capacitive touch printed circuit board (PCB) 240. The capacitive touch PCB 240 may be located behind (e.g., along the rear surface of) the user interface 202 (e.g., the actuation member 210) for detecting actuations of the front surface 215 of the actuation member 210. The capacitive touch PCB 240 may be planar. The capacitive touch PCB 240 may include one or more pads located adjacent to (e.g., but not immediately behind) the light bar 220 for detecting touch actuations of or along the light bar 220 (e.g., and/or touch actuations of the front surface 215 of the actuation member 210 adjacent to the light bar 220). In some examples, the capacitive touch PCB 240 is not located immediately behind the light bar 220 since the light pipe 236 may extend from the light sources 238 in the enclosure 230 to the light bar 220. Further, the capacitive touch PCB 240 may be mounted or affixed to the actuation member 210, for example, such that movement or the actuation member 210 causes movement of the capacitive touch PCB 240. That is, the capacitive touch PCB 240 creates the touch sensitive surface on the front side of actuation member 210, and as such, the touch surface also moves with tactile actuations of the actuation member 210. One will appreciate that the capacitive touch PCB 240 may be located at other locations relative to the light bar.

As shown in FIG. 9, the capacitive touch PCB 240 may include a capacitive touch controller and one or more receiving capacitive touch pads 244 for detecting the touch actuations on or adjacent to the light bar 220. The receiving capacitive touch pads 244 may be arranged in a linear array that extends from the top to the bottom of the capacitive touch PCB 240. The capacitive touch PCB 240 (e.g., the capacitive touch controller) may be configured to detect the position of the touch actuation along the length of the light bar 220 in response to touch actuations received from the one or more receiving capacitive touch pads 244 and to control the electrical load(s) according to the determined position. For example, the capacitive touch PCB 240 (e.g., the capacitive touch controller) may provide an output signal to the main PCB 260, and the main PCB 260 may control the electrical load(s) based on the determined position (e.g., by controlling a drive circuit of the fan-speed control device 200, by sending a message, such as a digital message, to the electrical load and/or to a system controller that may communicate with the electrical load, etc.). The capacitive touch PCB 240 may be electrically connected to the main PCB 260 via a cable 246 (e.g., a ribbon cable) connected to a first connector 248 on the main PCB 260 and a second connector 249 on the capacitive touch PCB 240 (e.g., as shown in FIG. 6A).

The capacitive touch pads 244 may include one or more electrodes. For example, as shown in FIG. 6A, the diffuser 234 may be located between actuation member 210 and the capacitive touch pads 244 on the capacitive touch PCB 240, such there may not be any space (e.g., air) between the actuation member 210 and the capacitive touch pads 244 to improve the sensitivity of the capacitive touch controller. The capacitive touch PCB 240 may receive power via the cable 246 from a power supply of the main PCB 260 to power the components of the capacitive touch PCB 240.

The actuation member 210 may include pivot arms 252 (on respective sides thereof) that enable the actuation member 210 to pivot about the pivot axis 208 in response to respective tactile actuation of the upper portion 216 and the lower portion 218. As described herein, the capacitive touch PCB 240 may be mounted to the actuation member 210. Accordingly, the capacitive touch PCB 240 may move (e.g. pivot) when the actuation member 210 pivots in response to a tactile actuation of the upper or lower portion 216, 218. The pivot arms 252 may define the pivot axis 208 of the actuation member 210. The capacitive touch PCB 240 may create the touch sensitive surface on the front surface 215 of the actuation member 210, and as such, the touch sensitive surface may also move with tactile actuations of the actuation member 210. In examples, the capacitive touch PCB 240 may be a solid PCB (e.g., PCB with a solid substrate). In examples, the capacitive touch PCB 240 may be a flexible PCB (e.g., PCB with a flexible substrate) to enable further movement or bend of the capacitive touch PCB 240 in response to tactile actuations of the actuation member 210.

The tactile actuation of the actuation member 210 may cause one of the first and second tactile switches 264, 265 of the main PCB 260 to be actuated. For example, when the upper portion 216 of the actuation member 210 is actuated, the diffuser 234 may be moved toward the main PCB 260. The diffuser 234 may contact a rubber membrane 250 (e.g., rubber membrane extension 256) which may deflect inward (e.g., toward the main PCB 260) to actuate the first tactile switch 264 of the main PCB 260. Similarly, when the lower portion 218 of the actuation member 210 is actuated, the diffuser 234 may be moved toward the main PCB 260. The diffuser 234 may contact the rubber membrane 250 (e.g., rubber membrane extension 258), which may deflect inward (e.g., toward the main PCB 260) to actuate the second tactile switch 265 of the main PCB 260. Accordingly, the capacitive touch PCB 240 may be affixed to the actuation member 210, and the actuation member 210, when actuated, may pivot to actuate a tactile switch on a separate main PCB 260 of the fan-speed control device 200. As such, tactile actuations of the actuation member 210 may cause movement of the capacitive touch PCB 240 (e.g., and the diffuser 234).

Further, it should also be appreciated that the diffuser 234 may be configured to perform multiple functions. For example, the diffuser 234 may be configured to diffuse light emitted from light sources 238 located inside the enclosure 230 to the light bar 220 located on the front surface 215 of the actuation member 210, and may also be configured to cause the actuation of one or more of the tactile switches 264, 265 located on the main PCB 260. Stated differently, the diffuser 234 may be configured to transfer movement of the actuation member 210 to the tactile switches 264, 265, for example, via the capacitive touch PCB 240 and/or the rubber membrane 250.

In alternate examples, the capacitive touch PCB 240 may include tactile switches on a surface of the capacitive touch PCB, such as the back surface of the capacitive touch PCB 240 (e.g., rather than including the tactile switches 264, 265 on the main PCB 260). In such embodiments, the tactile switches of the capacitive touch PCB 240 would be actuated in response to tactile actuations of the upper portion 216 and the lower portion 218 of the actuation member 210. That is, tactile actuations of the actuation member 210 would cause the upper portion 216 or the lower portion 218 to move into the tactile switches of the capacitive touch PCB 240, for example, to actuate the tactile switches and/or to cause actuation of the tactile switches.

The capacitive touch PCB 240 may comprise a plurality of (e.g., five) receiving capacitive touch pads 244 (e.g., capacitive touch regions A-E) as shown in FIG. 9. The receiving capacitive touch pads 244 may each be triangular in shape and may be arranged in a linear array that extends from the top to the bottom of the capacitive touch PCB 240 (e.g., on the right side of the capacitive touch PCB 240). For example, the capacitive touch region A and the capacitive touch region E of the receiving capacitive touch pads 244 may be electrically coupled together.

Although described as a capacitive touch PCB 240, in some examples, the fan-speed control device 200 may include any PCB, such as the main PCB 260, at the position where the capacitive touch PCB 240 is illustrated in FIGS. 4 and 9. In such examples, the PCB may be located behind (along the rear surface of) the actuation member 210. This PCB may include any combination of circuitry, such as any combination of the circuitry described with reference to the capacitive touch PCB 240, the main PCB 260, a communication circuit (e.g., a wireless communication circuit), and/or a sensing circuit (e.g., a proximity sensing circuit, an ambient light sensing circuit, etc.). As such, the PCB may both move in response to actuations of the actuation member 210 and perform the functions enabled by the relevant circuitry (e.g., control external electrical loads like ceiling fans, control internal or external light sources based on feedback from an ambient light sensor and/or a proximity sensor, wirelessly transmit control signals to external electrical loads, etc.).

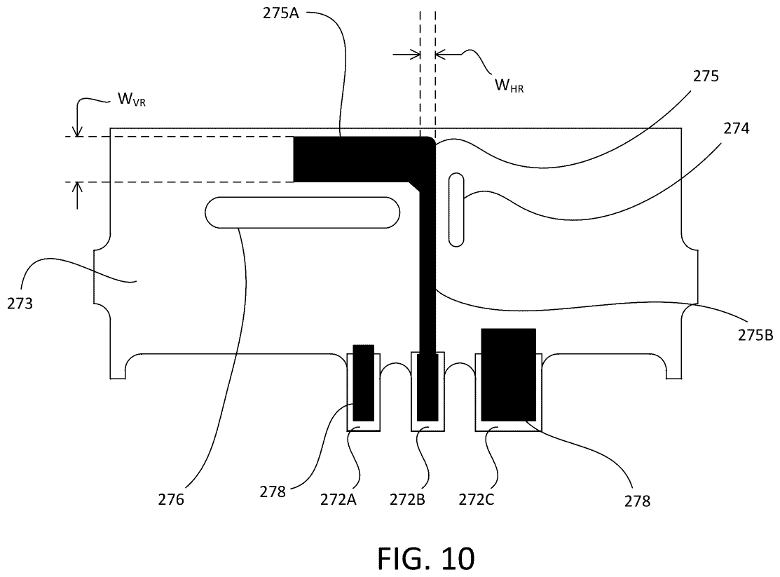

The fan-speed control device 200 may be configured to transmit and receive wireless messages, e.g., radio-frequency (RF) signals. The fan-speed control device 200 may include an antenna 275 and a communication circuit (e.g., such as antenna and wireless communication circuit as shown in FIG. 11). The wireless communication circuit may comprise an RF transceiver coupled to the antenna 275 for transmitting and/or receiving RF signals. In addition, the wireless communication circuit may comprise an RF transmitter for transmitting RF signals, and an RF receiver for receiving RF signals. The fan-speed control device 200 may include an antenna PCB 270. FIG. 10 is a side view of the antenna PCB 270. The antenna PCB 270 may define a first surface 271 (FIG. 8) and a second surface 273. The antenna PCB 270 may include the antenna 275. The antenna 275 may be a monopole antenna that is configured to operate at 2.4 GHz. The antenna 275 may be configured to transmit and/or receive the wireless signals (e.g., the RF signals). The antenna 275 may be located on the second surface 273 of the antenna PCB 270. The wireless communication circuit may be coupled to the antenna 275 for transmitting and/or receiving messages that include command(s) for controlling one or more electrical loads via the RF signals. The wireless communication circuit may determine and transmit the one or more commands for controlling the one or more electrical loads based on the inputs from the capacitive touch PCB 240 and/or the actuation member 210. Alternatively and/or in addition, the fan-speed control device 200 may control a motor load control circuit to control the amount of power delivered to the electrical load in response to a command received via the wireless communication circuit. The fan-speed control device 200 may determine a command to transmit via the wireless communication circuit based on user input on the actuation member 210.

The antenna PCB 270 may be configured to be received by (e.g., connected to) the main PCB 260. When the antenna PCB 270 is connected to the main PCB 260, the second surface 273 may be facing the light pipe 236 and the first surface 271 may be facing away from the light pipe 236. The antenna PCB 270 may include a plurality of fingers 272A, 272B, 272C that are configured to connect the antenna PCB 270 to the main PCB 260. For example, one or more of the fingers 272A, 272B, 272C may include conductors (e.g., gold-plated conductors) that are configured to contact corresponding contacts on the main PCB 260. The main PCB 260 may define openings 262A, 262B, 262C that are configured to receive the fingers 272A, 272B, 272C. The fingers 272A, 272B, 272C may be soldered into the openings 262A, 262B, 262C to provide mechanical and electrical connection between the antenna PCB 270 and the main PCB 260. In addition, when the fingers 272A, 272B, 272C are received by the openings 262A, 262B, 262C, frictional forces may retain the connection between the antenna PCB 270 and the main PCB 260. The antenna 275 of the antenna PCB 270 may be electrically connected to the wireless communication circuit on the main PCB 260 via the middle finger 272B. The additional outside fingers 272A, 272C may provide additional mechanical support for the antenna PCB 270. The finger 272C may be wider than fingers 272A, 272B, for example, as shown in FIGS. 6B and 10. It should be appreciated that the fingers 272A, 272B, 272C are not limited to the geometry shown in FIGS. 6B. and 10. Rather, the fingers 272A, 272B, 272C may define any respective width(s). Additionally or alternatively, the antenna PCB 270 may include more or less fingers than the three fingers 272A, 272B, 272C shown in FIGS. 6 and 10.

The antenna PCB 270 may be configured such that a portion of the antenna 275 protrudes through an opening 242 defined by the yoke 232 (e.g., as shown in FIGS. 7 and 8). For example, the antenna 275 may extend from a location proximate to the main PCB 260 through the opening 242. The opening 242 may define a first portion 242A that is configured to receive a portion of the antenna PCB 270 and a second portion 242B that is configured to receive the cable 246 connected between the capacitive touch PCB 240 and the main PCB 260. For example, the second portion 242B may be configured to enable electrical connection of the capacitive touch PCB 240 to the main PCB 260. The first portion 242A may be longer than the second portion 242B, for example, to receive the antenna PCB 270. The first portion 242A of the opening 242 may define a length L_{OP1} and the second portion 242B of the opening 242 may define a length L_{OP2}. The length L_{OP1} of the first portion 242A may be greater than the length L_{OP2} of the second portion 242B. It should be appreciated that the opening 242 may define different geometry than shown in FIG. 8. For example, the length L_{OP1} and the length L_{OP2} may be equal such that the opening 242 is rectangular. In examples, the length L_{OP2} may be greater than the length L_{OP1} such that the first portion 242A is longer than the second portion 242B.

The portion of the antenna 275 that protrudes through the opening 242 may be located within a cavity 277 defined by the actuation member 210, the bezel 206, and the yoke 232. For example, the antenna 275 may extend from the location proximate to the main PCB 260 through the opening 242 in the yoke 232 and into the cavity 277. A horizontal trace 275B of the antenna 275 may extend from the location proximate to the main PCB 260 through the opening 242 in the yoke 232 and into the cavity 277. The horizontal trace 275B may be connected to a vertical trace 275A of the antenna 275. The vertical trace 275A may be located within the cavity 277 (e.g., entirely within the cavity 277) when the antenna PCB 270 is attached to the main PCB 260.

When the fan-speed control device 200 is mounted in a metal wallbox, the yoke 232 and the metal wallbox may form a shielded volume around the electrical circuitry on the main PCB 260 (e.g., including the wireless communication circuit). Locating the portion of the antenna 275 within the cavity 277 may allow the vertical trace 275A to be positioned in front of the yoke 232 (e.g., between the yoke 232 and the actuation member 210), for example, to allow electrical fields to be generated by and/or received by the antenna 275 and to help avoid interference with metal portions of the fan-speed control device 200 (e.g., the yoke 232 and/or a metal faceplate). The material (e.g., substrate) of the antenna PCB 270 proximate to the antenna 275 may introduce loss and decrease performance of the antenna 275. The antenna PCB 270 may define slot(s) 274, 276 proximate to the antenna 275. The slots(s) 274, 276 may be located within the cavity 277 when the antenna PCB 270 is attached to the main PCB 260. The slot(s) 274, 276 may be configured to reduce an amount of board material proximate to the antenna 275 such that the performance of the antenna 275 is improved. The slot(s) 274, 276 may extend through the antenna PCB 270. For example, the slot(s) 274, 276 may extend from the first surface 271 of the antenna PCB 270 to the second surface 273 of the antenna PCB 270.

The main PCB 260 may include a ground plane 266 (e.g., on a front side of the main PCB 260). The antenna 275 may extend perpendicularly from the main PCB 260 (e.g., the ground plane 266). For example, the ground plane 266 may be configured as a counterpoise for the antenna 275. The counterpoise for the antenna 275 may be located on the main PCB 260. The ground plane 266 may be located within the fan-speed control device 200 (e.g., inside of the yoke 232, the enclosure ring 280, and the rear enclosure 230), such that the counterpoise for the antenna 275 may be located on an opposite side of the yoke 232 than the vertical trace 275A of the antenna 275 (e.g., the counterpoise may be submerged in the wallbox in which the fan-speed control device 200 is installed). The second portion 242B of the opening 242 in the yoke 232 may be located over the ground place 266. The second portion 242B of the opening 242 may allow electrical fields to be generated by and/or received by the antenna 275.

The antenna 275 may be a bent pole antenna. For example, the antenna 275 may include a horizontal trace 275B and a vertical trace 275A. The antenna PCB 270 and the vertical trace 275A may be configured such that the antenna 275 is as close to vertical midpoint of the fan-speed control device 200 (e.g., which may be defined by the pivot axis 208) as possible (e.g., without causing interference with the actuation member 210 and/or the capacitive touch PCB 240). The horizontal trace 275B may extend from the finger 272B to the vertical trace 275A. The finger 272B may be configured to connect the antenna 275 to the wireless communication circuit on the main PCB 260. The vertical trace 275A may have a width W_{VR} and the horizontal trace 275B may have a width W_{HR}. The width W_{VR} of the vertical trace 275A may be greater than the width W_{HR} of the horizontal trace 275B. The width W_{VR} of the vertical trace 275A may be sized to maximize the amount of the antenna 275 in front of the yoke 232, for example, as shown in FIGS. 6B and 7. Maximizing the amount of the antenna 275 in front of the yoke 232 may mitigate interference and increase bandwidth capabilities of the antenna 275. The antenna PCB 270 may comprise pads 278 that are configured to attach (e.g., mount) the antenna PCB 270 to the main PCB 260. For example, the pads 278 may be located on fingers 272A, 272C. It should be appreciated that the vertical trace 275A and the horizontal trace 275B of the antenna 275 are not limited to the geometry shown in FIG. 10. In examples, the width W_{HR} of the horizontal trace 275B may be reduced and the width W_{VR} of the vertical trace 275A may be increased. It should also be appreciated that although the figures show the antenna 275 on the second surface 273, the antenna 275 may be on the first surface 271 of the antenna PCB 270.

FIG. 11 is a simplified block diagram of an example control device 300 (e.g., a fan-speed control device) that may be deployed as, for example, the fan-speed control device 120 of the load control system 100 shown in FIG. 1 and/or the fan-speed control device 200 shown in FIGS. 2A-9. The control device 300 may include a hot terminal H that may be adapted to be coupled to a power source 302, such as an alternating-current (AC) power source. In some examples, the power source 302 may comprise a direct-current (DC) power source. The control device 300 may include a controlled-hot terminal CH that may be adapted to be coupled to an electrical load, such as a motor load 304, such as a motor of a ceiling fan (e.g., the motor 112 of the ceiling fan 110). The control device 300 may include a motor load control circuit 310 coupled in series electrical connection between the power source 302 and the motor load 304. The motor load control circuit 310 may be configured to control the power delivered to the motor load 304. The control device 300 may include a device control circuit 320 configured to control the motor load control circuit 310 to control the power delivered to the motor load 304 to thus control a rotational speed ωmotor of the motor load 304. The device control circuit 320 may include one or more of a processor (e.g., a microprocessor), a microcontroller, a programmable logic device (PLD), a field programmable gate array (FPGA), an application specific integrated circuit (ASIC), or any suitable controller or processing device.

The motor load control circuit 310 may comprise a first controllable switching circuit 311, a second controllable switching circuit 312, and a third controllable switching circuit 313. For example, the first, second, and third controllable switching circuits 311, 312, 313 may each comprise a bidirectional semiconductor switch, such as a thyristor (e.g., a triac or one or more silicon-controlled rectifiers), a field-effect transistor (FET) in a rectifier bridges, two FETs in anti-series connection, one or more insulated-gate bipolar junction transistors (IGBTs), or other suitable bidirectional semiconductor switches. In addition, the first, second, and third controllable switching circuits 311, 312, 313 may each comprise a relay or other suitable controllably conductive device. The device control circuit 320 may be configured to control (e.g., independently control) the first, second, and third controllable switching circuits 311, 312, 313 to render the first, second, and third controllable switching circuits 311, 312, 313 conductive and non-conductive.

The first controllable switching circuit 311 may be coupled in series with a first capacitor C314, such that the series combination of the first controllable switching circuit 311 and the first capacitor C314 may be coupled in series between the hot terminal H and the controlled-hot terminal CH. The second controllable switching circuit 312 may be coupled in series with a second capacitor C315, such that the series combination of the second controllable switching circuit 312 and the second capacitor C315 may be coupled in series between the hot terminal H and the controlled-hot terminal CH. For example, the first and second capacitors C314, C315 may have different capacitances, e.g., approximately 3.3 μF and 5.6 μF, respectively. The third controllable switching circuit 313 may be coupled (e.g., directly coupled) in series between the hot terminal H and the controlled-hot terminal CH. The series combination of the first controllable switching circuit 311 and the first capacitor C314, the series combination of the second controllable switching circuit 312 and the second capacitor C315, and the third controllable switching circuit 313 may be coupled in parallel with each other. In addition, the motor load control circuit 310 may comprise a first resistor R316 coupled in parallel with the first capacitor C314 for discharging the first capacitor C314 when the first controllable switching circuit 311 is non-conductive, and a second resistor R318 coupled in parallel with the second capacitor C315 for discharging the second capacitor C315 when the second controllable switching circuit 312 is non-conductive. For example, the first resistor R316 and the second resistor R318 may each have a resistance of approximately 130 kΩ.

The device control circuit 320 may be configured to render (e.g., independently render) the first, second, and third controllable switching circuits 311, 312, 313 conductive and non-conductive to control a magnitude of a load current I_{LOAD} conducted through the motor load 304 to control a rotational speed ωₘₒₜₒᵣ of the motor load 304 to a plurality of discrete speeds (e.g., four discrete speeds). The device control circuit 320 may be configured to render the first controllable switching circuit 311 conductive to electrically couple the first capacitor C314 in series between the power source 302 and the motor load 304 to control the rotational speed ωₘₒₜₒᵣ of the motor load 304 to a first speed ω₁ (e.g., a minimum or low speed). The device control circuit 320 may be configured to render the second controllable switching circuit 312 conductive to electrically couple the second capacitor C315 in series between the power source 302 and the motor load 304 to control the rotational speed ωₘₒₜₒᵣ of the motor load 304 to a second speed ω2 (e.g., a medium-low speed). The device control circuit 320 may be configured to render the first controllable switching circuit 311 and the second controllable switching circuit 312 conductive to electrically couple the first capacitor C314 and the second capacitor C315 in parallel between the power source 302 and the motor load 304 to control the rotational speed ωₘₒₜₒᵣ of the motor load 304 to a third speed ω₃ (e.g., a medium-high speed). The device control circuit 320 may be configured to render the third controllable switching circuit 313 conductive to bypass the first capacitor C314 and the second capacitor C315 to control the rotational speed ωₘₒₜₒᵣ of the motor load 304 to a fourth speed ω4 (e.g., a maximum or high speed). One will appreciate other similar configurations are possible to obtain more or less than four discrete speeds.

The control device 300 may comprise a zero-crossing detector 322 (e.g., a zero-cross detect circuit) electrically coupled between the hot terminal H and the controlled-hot terminal CH. The zero-crossing detector 322 may be configured to generate a zero-cross detect signal V_{ZC} that indicates the zero-crossing points of an AC mains line voltage generated by the power source 302. The device control circuit 320 may receive the zero-cross detect signal V_{ZC} and may be configured to render the first, second, and third controllable switching circuits 311, 312, 313 of the motor load control circuit 310 based on the zero-cross detect signal V_{ZC}. For example, the device control circuit 320 may be configured to render the first, second, and third controllable switching circuits 311, 312, 313 conductive and non-conductive at approximately the zero-crossings of the AC mains line voltage as determined from the zero-cross detect signal V_{ZC} received from the zero-crossing detector 322.

The control device 300 may include a memory 324. The memory 324 may be communicatively coupled to the device control circuit 320 for the storage and/or retrieval of, for example, operational settings, such as, the present rotational speed ωₘₒₜₒᵣ of the motor load 304. The memory 324 may be implemented as an external integrated circuit (IC) or as an internal circuit of the control circuit 320. The memory 324 may comprise a computer-readable storage media or machine-readable storage media that maintains computer-executable instructions for performing one or more procedure and/or functions as described herein. For example, the memory 324 may comprise computer-executable instructions or machine-readable instructions that when executed by the control circuit configure the control circuit to provide one or more portions of the procedures described herein. The control circuit 320 may access the instructions from memory 324 for being executed to cause the control circuit 320 to operate as described herein, or to operate one or more other devices as described herein. The memory 324 may comprise computer-executable instructions for executing configuration software. For example, the operational characteristics stored in the memory 324 may be configured during a configuration procedure of the control device 300.

The control device 300 may include a power supply 326. The power supply 326 may generate a direct-current (DC) supply voltage V_{CC} for powering the device control circuit 320 and the other low-voltage circuitry of the control device 300. The power supply 326 may be coupled between the hot terminal H and the controlled-hot terminal CH (e.g., in parallel with the motor load control circuit 310). The power supply 326 may be configured to conduct a charging current through the motor load 304 to generate the DC supply voltage V_{CC}.

The control device 300 may comprise a communication circuit 330, e.g., such as a wired communication circuit or a wireless communication circuit. The communication circuit 330 may include for example, a radio-frequency (RF) transceiver coupled to an antenna 332 (e.g., the antenna 275 shown in FIGS. 6, 7, and 10) for transmitting and/or receiving RF signals. The communication circuit 330 may also include an RF transmitter for transmitting RF signals, an RF receiver for receiving RF signals, or an infrared (IR) transmitter and/or receiver for transmitting and/or receiving IR signals. The communication circuit 330 may be configured to transmit a control signal that includes the control data (e.g., a digital message) generated by the device control circuit 320. In addition, the device control circuit 320 may be configured to receive messages (e.g., digital messages) that include control data (e.g., a command) for controlling the motor load 304 via the communication circuit 330. The device control circuit 320 may be configured to control the motor load control circuit 310 to adjust the rotational speed ωₘₒₜₒᵣ and/or the direction of the motor load 304 in response to control data received via the messages.

The device control circuit 320 may be responsive to user inputs received from actuators 340 (e.g., the tactile switches 264, 265 on the main PCB 260). The device control circuit 320 may control the motor load control circuit 310 to adjust the rotational speed ωₘₒₜₒᵣ of the motor load 304 in response to the user inputs (e.g., tactile actuations) received via the actuators 340. The device control circuit 320 may receive respective actuator signals from the actuators 340 in response to tactile actuations of the actuators 340 (e.g., in response to movements of an actuation member, such as the actuation member 210). For example, the actuators 340 may be actuated in response to tactile actuations of an upper portion and/or a lower portion of the actuation member.

In addition, the device control circuit 320 may be responsive to user inputs received from a touch sensitive device 350. The device control circuit 320 may control the motor load control circuit 310 to adjust the rotational speed ωₘₒₜₒᵣ of the motor load 304 in response to the user inputs (e.g., touch actuations) received via the touch sensitive device 350. The touch sensitive device 350 may be configured to detect touch actuations (e.g., point actuations and/or gestures, where, for example, the gestures may be effectuated with or without physical contacts with the touch sensitive device 350), and provide respective one or more output signals V_{OUT} to the device control circuit 320 indicating the touch actuations (e.g., indicating a position of one or more touch actuations). The touch sensitive device 350 may detect a touch actuation of the front surface along the light bar and cause the device control circuit 320 to adjust the rotational speed ωₘₒₜₒᵣ of the motor load 304 accordingly. The device control circuit 320 may be configured to translate the actuator signals received from the actuators 340 and/or the output signals V_{OUT} received from the touch sensitive device 350 into control data (e.g., one or more control signals). The device control circuit 320 may use the control data to control the motor load control circuit 310 to adjust the rotational speed ωₘₒₜₒᵣ of the motor load 304 (e.g., via the motor load control circuit 310 and/or by transmitting a control signal (such as to the motor load 304) that includes control data (e.g., a digital message)).

The touch sensitive device 350 may include a capacitive touch circuit 352 and a user interface control circuit 354 (e.g., which may be an example of the capacitive touch controller). The capacitive touch circuit 352 that comprises one more capacitive touch elements. For example, the capacitive touch circuit 352 may comprise one or more capacitive touch pads, such as the receiving capacitive touch pads 244 mounted to the capacitive touch PCB 240 of the fan-speed control device 200. In addition, the capacitive touch circuit 352 may comprise one or more capacitive transmission traces 245. The capacitive touch circuit 352 may provide one or more capacitive receive signals V_{RX-A}-V_{RX-E} from the capacitive touch pads of the capacitive touch circuit 352 (e.g., from regions A-E of the receiving capacitive touch pads 244 mounted to the capacitive touch PCB 240 of the fan-speed control device 200), where each capacitive receive signal V_{RX-A}-V_{RX-E} indicates the capacitance of a capacitive touch pad.

The user interface control circuit 354 may include one or more of a processor (e.g., a microprocessor), a microcontroller, a programmable logic device (PLD), a field programmable gate array (FPGA), an application specific integrated circuit (ASIC), or any suitable controller or processing device. The user interface control circuit 354 may include a memory and/or may use the memory 324. The user interface control circuit 354 may be configured to determine or detect a change in the capacitances of the capacitive touch pads of the capacitive touch circuit 352 (e.g., due to a user's finger actuating the front surface 215 of the actuation member 210), and generate the output signal V_{OUT} in accordance with the change in capacitance of the capacitive touch pads. The output signal V_{OUT} may indicate a position of a touch actuation along the front surface of the actuation member (e.g., over the light bar 220). As noted above, the user interface control circuit 354 may receive one or more capacitive receive signals V_{RX-A}-V_{RX-E} from the capacitive touch pads of the capacitive touch circuit 352 (e.g., from regions A-E of the receiving capacitive touch pads 244 mounted to the capacitive touch PCB 240 of the fan-speed control device 200), where each capacitive receive signal V_{RX-A}-V_{RX-E} indicates the capacitance of a capacitive touch pad.

The user interface control circuit 354 may be configured to determine the position of the touch actuation along the front surface of the actuation member (e.g., along the light bar 220) in response to the receive signals V_{RX-A}-V_{RX-E} generated by the receiving capacitive touch pads. In response, the user interface control circuit 354 may generate and provide the output signal V_{OUT} to the device control circuit 320. For example, the user interface control circuit 354 may be configured to charge capacitances of the capacitive touch pads of the capacitive touch circuit 352. For example, although not illustrated, the capacitive touch pads of the capacitive touch circuit 352 may be coupled to user interface control circuit 354 via a capacitive transmitting circuit (not shown) and/or a capacitive receiving circuit (not shown). The user interface control circuit 354 may be configured to control the capacitive transmitting circuit to charge capacitances of the capacitive touch pads (e.g., the capacitive touch pads 244) of the capacitive touch circuit 352. For example, the capacitive transmitting circuit may be configured to control a capacitive transmitting signal VTx to pull the transmission traces (e.g., the transmission traces 245) of the capacitive touch circuit 352 up towards the supply voltage V_{CC} to charge the capacitances of the capacitive touch pads.

The user interface control circuit 354 may step through each of the capacitive touch pads of the capacitive touch circuit 352 and process the capacitive receive signals V_{RX-A}-V_{RX-E} to detect a change in the capacitance of the respective capacitive touch pad. For example, the user interface control circuit 354 may periodically charge the capacitance of each of the capacitive touch pads of the capacitive touch circuit 352 and then discharge the capacitance of the respective touch pad into a capacitor (not shown) of the user interface control circuit 354 (e.g., which may have a much larger capacitance than the capacitance of each of the capacitive touch pads of the capacitive touch circuit 352). The user interface control circuit 354 may be configured to compare the voltage across the capacitor of the touch sensitive device 350 to a voltage threshold VTH and generate an output signal V_{OUT}, which may indicate when the voltage across the capacitor of the touch sensitive device 350 exceeds the voltage threshold VTH. For example, the user interface control circuit 354 may charge and discharge the capacitance of each capacitive touch pad a predetermined number of time (e.g., approximately 500 times) during a sensing interval (e.g., approximately 500 μsec) before moving on the next capacitive touch pad of the capacitive touch circuit 352. The user interface control circuit 354 may be configured to compare a measured voltage provided via one or more of the capacitive touch pads to a voltage threshold. The user interface control circuit 354 may generate an output signal that indicates when the measured voltage exceeds the voltage threshold. The user interface control circuit 354 may be configured to use different voltage thresholds for different capacitive touch pads. For example, the capacitive touch pads may be separated from the touch sensitive surface by varying distances and the different voltage thresholds used may be based on the distance(s) between the capacitive touch pads and the touch sensitive surface.

The user interface control circuit 354 may be configured to determine a count N_{CAP} that indicates how many times the capacitance of the respective capacitive touch pad was charged and discharged before the voltage across the capacitor of the touch sensitive device 350 exceeds the voltage threshold VTH. The count N_{CAP} may indicate the present capacitance of the respective capacitive touch pad of the capacitive touch circuit 352. The count N_{CAP} for each of the capacitive touch pads of the capacitive touch circuit 352 may represent a sample of the present capacitance of the respective touch pad during the preceding sensing interval. The user interface control circuit 354 may be configured to process the count N_{CAP} to determine the present capacitance of the respective touch pad of the capacitive touch circuit 352 using a respective baseline count N_{BL} for each of the capacitive touch pads of the capacitive touch circuit 352. The baseline count N_{BL} may indicate an idle capacitance of each of the capacitive touch pads when the front surface of the actuation member (e.g., the light bar) is not being actuated. The user interface control circuit 354 may be configured to determine the respective baseline counts N_{BL} for each of the capacitive touch pads of the capacitive touch circuit 352 when the front surface of the actuation member is not being actuated. For example, the baseline count N_{BL} may be a long-term average of the count N_{CAP} determined by the user interface control circuit 354 from the capacitive receive signals V_{RX-A}-V_{RX-E}.

After stepping through each of the capacitive touch pads of the capacitive touch circuit 352 (e.g., after a round of capacitive sensing of the capacitive touch pads), the user interface control circuit 354 may process the determined counts N_{CAP} for each of the respective capacitive touch pads of the capacitive touch circuit 352 to detect a touch actuation. The user interface control circuit 354 may be configured to determine a change Δ_{CAP} in the count (e.g., which may indicate the capacitance of each of the capacitive touch pad of the capacitive touch circuit 352) by determining the difference between the respective baseline count N_{BL} from the present count N_{CAP} of the respective capacitive touch pad, e.g., Δ_{CAP}=|N_{CAP}−N_{BL}|. The user interface control circuit 354 may be configured to determine that capacitive sensitive surface (e.g., the light bar) is being actuated when at least one of the changes Δ_{CAP} in count exceeds a capacitance-change threshold TH_{CAP}, which may represent an approximately 0.5% to 1% change in the capacitance, for example.

The user interface control circuit 354 may be configured to determine a number N_{TOUCH-IN} of times (e.g., a number of consecutive rounds of capacitive sensing) that the change Δ_{CAP} in count for one of the capacitive touch pads exceeds the capacitance-change threshold TH_{CAP}. The user interface control circuit 354 may be configured to enter an active touch mode when the number N_{TOUCH-IN} exceeds a touch-in threshold TH_{TOUCH-IN} (e.g., such as two, three, four, five, six, seven, or eight). For example, the user interface control circuit 354 may detect a touch actuation when the number N_{TOUCH-IN} exceeds a touch-in threshold TH_{TOUCH-IN}. When in the active touch mode, the user interface control circuit 354 may be configured to determine a number N_{TOUCH-OUT} of times (e.g., a number of consecutive rounds of capacitive sensing) that the change Δ_{CAP} in count for one of the capacitive touch pads does not exceed the capacitance-change threshold TH_{CAP}. The user interface control circuit 354 may be configured to exit the active touch mode when the number N_{TOUCH-OUT} exceeds a touch-out threshold TH_{TOUCH-OUT}.

While in the active touch mode, the user interface control circuit 354 may be configured to determine the position of the touch actuation along the touch sensitive surface (e.g., the light bar) in response to ratios of the changes Δ_{CAP} in the count for each of the capacitive touch pads of the capacitive touch circuit 352 (e.g., in response to the receive signals V_{RX-A}-V_{RX-E} generated by the receiving capacitive touch pads). For example, the ratio of the change Δ_{CAP} in the count for region B to the change Δ_{CAP} in the count for region C of the receiving capacitive touch pads 244 of the fan-speed control device 200 may indicate a position of a touch actuation along the light bar 220 between the regions B and C.

The user interface control circuit 354 may provide an output signal V_{OUT} to the device control circuit 320 in response to detecting a touch actuation along the touch sensitive surface of the control device 300 (e.g., in response to detecting a touch actuation along the light bar 220). The output signal V_{OUT} may indicate a position of the touch actuation along the front surface of the actuation member. The device control circuit 320 may be configured to translate the output signal V_{OUT} into control data (e.g., one or more control signals) for controlling one or more electrical loads. For example, the device control circuit 320 may use the control data to drive to control the motor load control circuit 310 to adjust the rotational speed ωₘₒₜₒᵣ of the motor load 304.

The user interface control circuit 354 may generate a touch actuation signal V_{ACT} that may indicate that a touch is present along the touch sensitive surface of the actuation member of the control device. The user interface control circuit 354 may provide the touch actuation signal V_{ACT} to the device control circuit 320. For example, the user interface control circuit 354 may drive the touch actuation signal V_{ACT} high upon detecting a touch actuation along the touch sensitive surface to indicate that the control device is operating in active touch mode, and otherwise drive the touch activation signal V_{ACT} low.

The device control circuit 320 may control the motor load control circuit 310 to adjust the rotational speed ωₘₒₜₒᵣ of the motor load 304 based on the position of the touch actuation along the front surface of the actuation member as determined from the output signal V_{OUT} generated by the user interface control circuit 354. For example, the device control circuit 320 may be configured to control the rotational speed ωₘₒₜₒᵣ of the motor load 304 to one of a plurality of discrete speeds (e.g., four speeds) depending upon which one of four regions along the light bar (e.g., the regions 211-214 of the touch sensitive surface on the actuation member 210 along the light bar 220) in which the position of the touch actuation occurs. The device control circuit 320 may be configured to control the rotational speed ωₘₒₜₒᵣ of the motor load 304 to the first speed ω₁ when the output signal V_{OUT} indicates that the position of the touch actuation is within a first region (e.g., the first region 211 along the light bar 220). The device control circuit 320 may be configured to control the rotational speed ωₘₒₜₒᵣ of the motor load 304 to the second speed ω2 when the output signal V_{OUT} indicates that the position of the touch actuation is within a second region (e.g., the second region 212 along the light bar 220). The device control circuit 320 may be configured to control the rotational speed ωₘₒₜₒᵣ of the motor load 304 to the third speed ω₃ when the output signal V_{OUT} indicates that the position of the touch actuation is within a third region (e.g., the third region 213 along the light bar 220). The device control circuit 320 may be configured to control the rotational speed ωₘₒₜₒᵣ of the motor load 304 to the fourth speed ω4 when the output signal V_{OUT} indicates that the position of the touch actuation is within a fourth region (e.g., the fourth region 214 along the light bar 220).

The device control circuit 320 may be configured to illuminate light sources 360 (e.g., the light sources 238) to provide feedback of a status (e.g., the rotational speed ωₘₒₜₒᵣ) of the motor load 304, in response to receiving indications of actuations of the actuators 340 and/or the capacitive touch pads, to indicate a status of the control device 300, and/or to assist with a control operation (e.g., to configure the control device 300, select an operational mode of the control device 300, etc.). For example, the light sources 360 may comprise one or more light-emitting diodes (LEDs). The light sources 360 may be configured to illuminate the light bar (e.g., the light bar 220) and/or to serve as indicators of various conditions. The device control circuit 320 may be configured to control the light sources 360 to illuminate the light bar to indicate which of the first, second, third, or fourth speeds ω₁-ω₄ that the control device 300 is presently controlling the motor load 304 (e.g., as shown in FIGS. 3A-3D or in FIGS. 4A-4D).

When the device control circuit 320 is controlling the rotational speed ωₘₒₜₒᵣ of the motor load 304 to the first speed ω₁, the device control circuit 320 may be configured to illuminate a first illuminated portion of the light bar (e.g., the first illuminated portion 221A or 221B of the light bar 220) to indicate the first speed ω₁. When the device control circuit 320 is controlling the rotational speed ωₘₒₜₒᵣ of the motor load 304 to the second speed ω₂, the device control circuit 320 may be configured to illuminate a second illuminated portion of the light bar (e.g., the second illuminated portion 222A or 222B of the light bar 220) to indicate the second speed ω₂. When the device control circuit 320 is controlling the rotational speed ωₘₒₜₒᵣ of the motor load 304 to the third speed ω3, the device control circuit 320 may be configured to illuminate a third illuminated portion of the light bar (e.g., the third illuminated portion 223A or 223B of the light bar 220) to indicate the third speed ω3. When the device control circuit 320 is controlling the rotational speed ωₘₒₜₒᵣ of the motor load 304 to the fourth speed ω₄, the device control circuit 320 may be configured to illuminate a fourth illuminated portion of the light bar (e.g., the fourth illuminated portion 224A or 224B of the light bar 220) to indicate the fourth speed ω₄.

Although described with reference to the user interface control circuit 354, it should be appreciated that in some examples the control device 300 may include a single control circuit, such as the device control circuit 320, and the processing performed by the user interface control circuit 354 may be performed by the device control circuit 320.

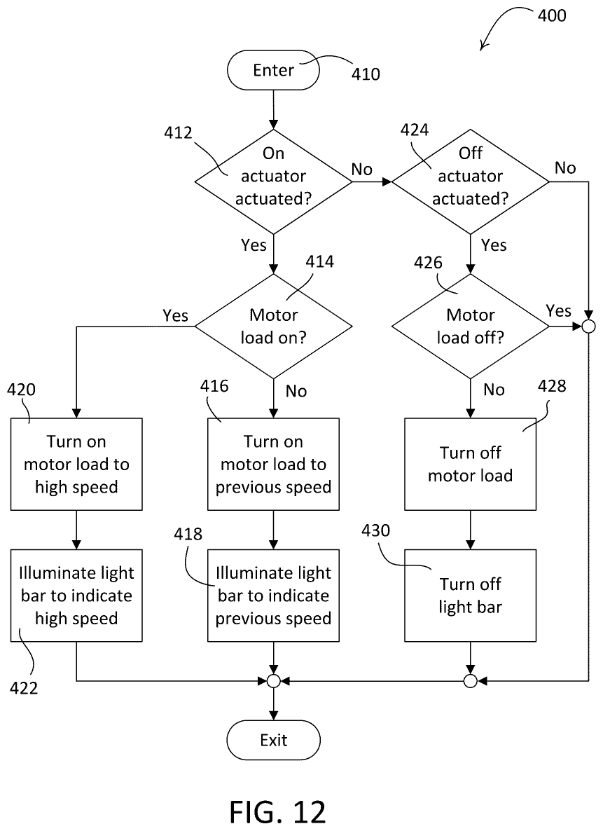

FIG. 12 is a flowchart of an example control procedure 400 to turn a motor load (e.g., the motor 112 of the ceiling fan 110 and/or the motor load 304) on and/or off. The control procedure 400 may be executed by a control circuit of a control device (e.g., a control circuit of the fan-speed control device 120, a control circuit of the fan-speed control device 200, and/or the control circuit 320 of the control device 300). For example, the control circuit may execute the control procedure 400 to process a tactile actuation of an upper portion or a lower portion of an actuation member (e.g., the upper portion 216 or the lower portion 218 of the actuation member 210) that causes the actuation member to pivot to actuate a tactile switch (e.g., one of the tactile switches 262, 264). The control circuit may execute the control procedure 400 at 410 periodically, and/or in response to detecting the tactile actuation of the upper portion or the lower portion of the actuation member.

If an on actuator was actuated at 412 (e.g., the upper portion 216 of the actuation member 210 was pressed to actuate the first tactile switch 262), the control circuit may determine if the motor load is presently on at 414. If the motor load is off at 414, the control circuit may turn on the motor load at 416 (e.g., by controlling the motor load and/or by sending a message, such as a digital message, to a load control device to control the motor load). For example, the device control circuit 320 of the control device 300 may control the motor load control circuit 310 to turn the motor load at 416 on to a previous rotational speed (e.g., before the motor load was previously turned off), which may be determined from operation settings stored in memory 324. At 418, the control circuit may control one or more light sources of the control device (e.g., the light sources 238 and/or the light sources 360) to illuminate a light bar (e.g., the light bar 220) to indicate rotational speed ωₘₒₜₒᵣ of the motor load 304, before the control procedure 400 ends. For example, the control circuit may be configured to illuminate a first illuminated portion of the light bar (e.g., the first illuminated portion 221A or 221B of the light bar 220) to indicate the first speed ω₁, to illuminate a second illuminated portion of the light bar (e.g., the second illuminated portion 222A or 222B of the light bar 220) to indicate the second speed ω₂, to illuminate a third illuminated portion of the light bar (e.g., the third illuminated portion 223A or 223B of the light bar 220) to indicate the third speed ω₃, and to illuminate a fourth illuminated portion of the light bar (e.g., the fourth illuminated portion 224A or 224B of the light bar 220) to indicate the fourth speed ω₄.

If the on actuator was actuated at 412, but the motor load was on at 414, the control circuit may adjust the rotational speed ωₘₒₜₒᵣ of the motor load 304 to the fourth speed ω₄ (e.g., the maximum or high speed) at 420 (e.g., by controlling the motor load and/or by sending a message, such as a digital message, to a load control device to control the motor load). For example, the device control circuit 320 of the control device 300 may control the motor load control circuit 310 to adjust the rotational speed ωₘₒₜₒᵣ of the motor load 304 to the fourth speed ω₄ at 420 (e.g., if the device control circuit 320 is not already controlling the motor load 304 to the fourth speed ω₄). At 422, the control circuit may control the one or more light sources to illuminate the light bar to indicate that the motor load is being controlled to indicate the fourth speed ω₄, before the control procedure 400 ends. For example, the control circuit may be configured to illuminate the fourth illuminated portion of the light bar (e.g., the fourth illuminated portion 224A or 224B of the light bar 220) to indicate the fourth speed ω₄.

If the on actuator was not actuated at 412, but an off actuator was actuated at 424 (e.g., the lower portion 218 of the actuation member 210 was pressed to actuate the second tactile switch 264), the control circuit may determine if the motor load is presently off at 426. If so, the control procedure 400 may simply exit. If the motor load is on at 426, the control circuit may turn off the motor load at 428 (e.g., by controlling the motor load and/or by sending a message, such as a digital message, to a load control device to control the motor load). For example, the device control circuit 320 of the control device 300 may control the motor load control circuit 310 to turn off the motor load at 428. At 430, the control circuit may control the one or more light sources (e.g., turn off the light sources) to cease illumination of the light bar to indicate that the motor load is off, before the control procedure 400 ends.

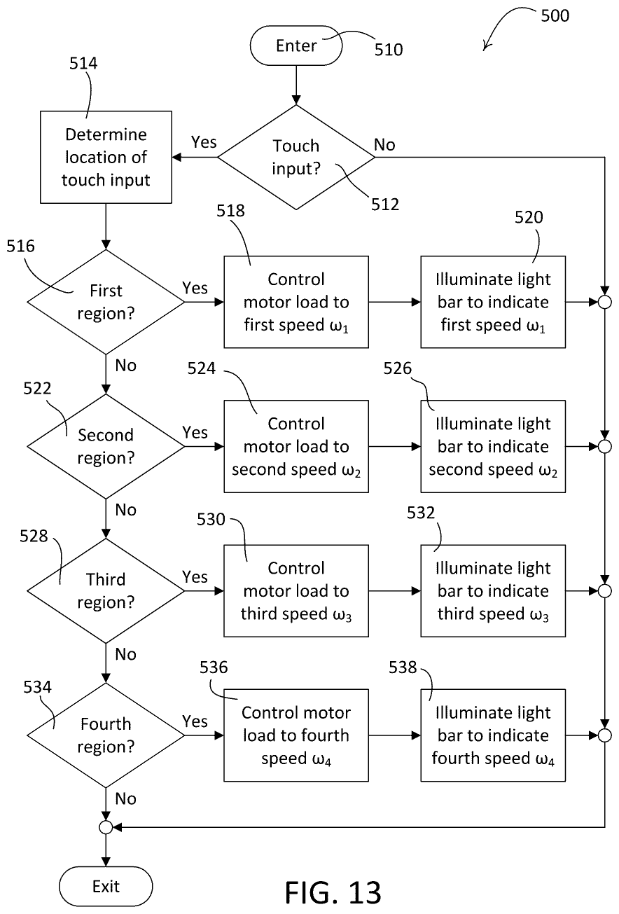

FIG. 13 is a flowchart of an example control procedure 500 to adjust a rotational speed ωₘₒₜₒᵣ of a motor load (e.g., the motor 112 of the ceiling fan 110 and/or the motor load 304). The control procedure 500 may be executed by a control circuit of a control device (e.g., a control circuit of the fan-speed control device 120, a control circuit of the fan-speed control device 200, and/or the control circuit 320 of the control device 300). For example, the control circuit may execute the control procedure 500 to process a touch actuation of the touch sensitive surface on a front surface of an actuation member (e.g., the front surface 215 of the actuation member 210) that does not cause the actuation member to pivot. The control circuit may execute the control procedure 500 at 510 periodically, and/or in response to detecting the touch actuation of the touch sensitive surface on the front surface of the actuation member.

At 512, the control circuit may determine if a touch actuation is presently occurring on the touch sensitive surface. If not, the control procedure 500 may end. If a touch actuation is presently occurring at 512, the control circuit may determine a position of the touch actuation on the touch sensitive surface along a light bar (e.g., the light bar 220) at 514. At 516, the control circuit may determine whether the position of the touch actuation along the light bar is within a first region (e.g., the first region 211). For example, the control circuit may determine whether the position of the touch actuation is within the first region 211 by comparing the position to one or more thresholds that define the limits of the first region 211 (e.g., limits that define the length and/or position of L_{R1} along light bar 220). When the position of the touch actuation is within the first region 211, the control circuit may adjust the rotational speed ωₘₒₜₒᵣ of the motor load to a first speed ω₁ (e.g., a minimum or low speed) at 518 (e.g., by controlling the motor load and/or by sending a message, such as a digital message, to a load control device to control the motor load). For example, the device control circuit 320 of the control device 300 may control the motor load control circuit 310 to adjust the rotational speed ωₘₒₜₒᵣ of the motor load 304 to the first speed ω₁ at 518. At 520, the control circuit may control one or more light sources of the control device to illuminate the light bar to indicate that the motor load is being controlled to indicate the first speed ω₁, before the control procedure 500 ends. For example, the control circuit may be configured to illuminate a first illuminated portion of the light bar (e.g., the first illuminated portion 221A or 221B of the light bar 220) to indicate the first speed ω₁ at 520.

If the position of the touch actuation along the light bar is not within the first region at 516, the control circuit may determine whether the position of the touch actuation along the light bar is within a second region (e.g., the second region 212) at 522. For example, the control circuit may determine whether the position of the touch actuation is within the second region 212 by comparing the position to one or more thresholds that define the limits of the second region 212 (e.g., limits that define the length and/or position of L_{R2} along light bar 220). When the position of the touch actuation is within the second region 212, the control circuit may adjust the rotational speed ωₘₒₜₒᵣ of the motor load to a second speed ω₂ (e.g., a medium-low speed) at 524 (e.g., by controlling the motor load and/or by sending a message, such as a digital message, to a load control device to control the motor load). For example, the device control circuit 320 of the control device 300 may control the motor load control circuit 310 to adjust the rotational speed ωₘₒₜₒᵣ of the motor load 304 to the second speed ω₂ at 524. At 526, the control circuit may control the one or more light sources to illuminate the light bar to indicate that the motor load is being controlled to indicate the second speed ω₂, before the control procedure 500 ends. For example, the control circuit may be configured to illuminate a second illuminated portion of the light bar (e.g., the second illuminated portion 222A or 222B of the light bar 220) to indicate the second speed ω2 at 526.

If the position of the touch actuation along the light bar is not within the second region at 522, the control circuit may determine whether the position of the touch actuation along the light bar is within a third region (e.g., the third region 213) at 528. For example, the control circuit may determine whether the position of the touch actuation is within the third region 213 by comparing the position to one or more thresholds that define the limits of the third region 213 (e.g., limits that define the length and/or position of L_{R3} along light bar 220). When the position of the touch actuation is within the third region 213, the control circuit may adjust the rotational speed ωₘₒₜₒᵣ of the motor load to a third speed ω₃ (e.g., a medium-high speed) at 530 (e.g., by controlling the motor load and/or by sending a message, such as a digital message, to a load control device to control the motor load). For example, the device control circuit 320 of the control device 300 may control the motor load control circuit 310 to adjust the rotational speed ωₘₒₜₒᵣ of the motor load 304 to the third speed ω₃ at 530. At 532, the control circuit may control the one or more light sources to illuminate the light bar to indicate that the motor load is being controlled to indicate the third speed ω₃, before the control procedure 500 ends. For example, the control circuit may be configured to illuminate a third illuminated portion of the light bar (e.g., the third illuminated portion 223A or 223B of the light bar 220) to indicate the third speed ω3 at 532.

If the position of the touch actuation along the light bar is not within the third region at 528, the control circuit may determine whether the position of the touch actuation along the light bar is within a fourth region (e.g., the fourth region 214) at 534. For example, the control circuit may determine whether the position of the touch actuation is within the fourth region 214 by comparing the position to one or more thresholds that define the limits of the fourth region 214 (e.g., limits that define the length and/or position of L_{R4} along light bar 220). When the position of the touch actuation is within the fourth region 214, the control circuit may adjust the rotational speed ωₘₒₜₒᵣ of the motor load to a fourth speed ω₄ (e.g., a maximum or high speed) at 536 (e.g., by controlling the motor load and/or by sending a message, such as a digital message, to a load control device to control the motor load). For example, the device control circuit 320 of the control device 300 may control the motor load control circuit 310 to adjust the rotational speed ωₘₒₜₒᵣ of the motor load 304 to the fourth speed ω₄ at 536. At 538, the control circuit may control the one or more light sources to illuminate the light bar to indicate that the motor load is being controlled to indicate the fourth speed ω₄, before the control procedure 500 ends. For example, the control circuit may be configured to illuminate a fourth illuminated portion of the light bar (e.g., the fourth illuminated portion 224A or 224B of the light bar 220) to indicate the fourth speed ω₄ at 538. Although described with reference to a particular order, the device control circuit 320 may be configured to determine if the position of the touch actuation along the light bar is within the first, second, third, or fourth regions in any order.

What is claimed is:

1. A control device for controlling a motor load, the control device comprising:
an actuation member having a front surface, the actuation member defining a touch sensitive surface along at least a portion of the front surface;
a plurality of light sources;
a light bar that is provided on the front surface and extends from a bottom end to a top end, the light bar configured to be illuminated by the plurality of light sources to indicate a rotational speed of the motor load; and
a control circuit configured to determine control data for controlling the motor load in response to actuations of the actuation member, the control circuit configured to determine first control data for turning the motor load on in response to an actuation of the actuation member, and second control data for turning the motor load off in response to an actuation of the actuation member, the control circuit further configured to determine that a touch actuation occurs along the touch sensitive surface and to determine third control data for adjusting a rotational speed of the motor load to one of a number of discrete speeds in response to which of a number of respective regions along the touch sensitive surface in which the touch actuation occurs;
wherein, when the motor load is on, the control circuit is configured to illuminate at least a portion of the light bar to indicate the one of the number of discrete speeds to which the rotational speed of the motor load is controlled in response to the third control data.

2. The control device of claim 1, the regions along the touch sensitive surface comprise a first region, a second region, a third region, and a fourth region that each comprise a respective length along the touch sensitive surface, and wherein the second region is located above the first region, the third region is located above the second region, and the fourth region is located above the third region; and
wherein the control circuit is configured to control the motor load to a first speed in response to an actuation of the touch sensitive surface within the first region, to a second speed in response to an actuation of the touch sensitive surface within the second region, to a third speed in response to an actuation of the touch sensitive surface within the third region, and to a fourth speed in response to an actuation of the touch sensitive surface within the fourth region.

3. (canceled)

4. (canceled)

5. The control device of claim 2, wherein the light bar comprises a continuous light bar, and the lengths of the first and fourth regions are each less than each of the lengths of the second and third regions, and wherein the lengths of the first and fourth regions are equal to each other, and the lengths of the second and third regions are equal to each other, such that the second and third regions meet at a point proximate a midpoint of the actuation member; and
wherein the control circuit is configured to illuminate a first portion of the light bar when the motor load is controlled to the first speed, a second portion of the light bar when the motor load is controlled to the second speed, a third portion of the light bar when the motor load is controlled to the third speed, and a fourth portion of the light bar when the motor load is controlled to the fourth speed.

6. (canceled)

7. (canceled)

8. The control device of claim 5, wherein the first portion extends from the bottom end to a first point on the light bar, the second portion extends from the bottom end to a second point on the light bar, the third portion extends from the bottom end to a third point on the light bar, and the fourth portion extends from the bottom end to a fourth point on the light bar.

9. The control device of claim 8, wherein the second point is at the midpoint of the light bar and the fourth point is at the top end of the light bar.

10. The control device of claim 8, wherein the first portion extends for 25% of the length of the light bar, the second portion extends for 50% of the length of the light bar, the third portion extends for 75% of the length of the light bar, and the fourth portion extends for 100% of the length of the light bar.

11. The control device of claim 8, wherein the first portion extends for a length equal to the length of the first region, the second portion extends for a length equal to the lengths of the first and second regions, the third portion extends for a length equal to the length of the first, second, and third regions, and the fourth portion extends for a length equal to the length of the first, second, third, and fourth regions.

12. The control device of claim 8, wherein the first portion extends into the second region, and the third portion extends a distance into the third region that is less than the length of the third region.

13. The control device of claim 5, wherein lengths of first, second, third, and fourth portions of the light bar are equal; and
wherein each of the lengths of first, second, third, and fourth illuminated portions are equal to approximately 25% of the length of the light bar.

14. (canceled)

15. The control device of claim 5, wherein the first portion extends from the bottom end to a first point on the light bar, the second portion extends from the first point on the light bar to a second point on the light bar, the third portion extends from the second point on the light bar to a third point on the light bar, and the fourth portion extends from the third point on the light bar to a fourth point on the light bar.

16. The control device of claim 15, wherein the second point is at the midpoint of the light bar and the fourth point is at the top end of the light bar.

17. The control device of claim 15, wherein each of the first portion, second, portion, third portion, and forth portion extends for a respective 25% of the length of the light bar.

18. The control device of claim 15, wherein the first portion extends for a length equal to the length of the first region, the second portion extends for a length equal to the length of second region, the third portion extends for a length equal to the length of third region, and the fourth portion extends for a length equal to the length of the fourth region.

19. The control device of claim 15, wherein the first portion extends into the second region, and the third portion extends a distance into the third region that is less than the length of the third region.

20. The control device of claim 2, wherein the lengths of the first, second, third, and fourth regions along the touch sensitive surface are equal to each other.

21. The control device of claim 1, wherein the actuation member comprises an upper portion and a lower portion and is configured to pivot about a pivot axis, wherein the control circuit is further configured to determine the first control data for turning the motor load on in response to an actuation of the upper portion the actuation member, and to determine the second control data for turning the motor load off in response to an actuation of the lower portion of the actuation member, and wherein the actuation member is configured to actuate a first tactile switch of the control device in response to a tactile actuation of the upper portion of the actuation member, and to actuate a second tactile switch of the control device in response to a tactile actuation of the lower portion of the actuation member.

22. (canceled)

23. The control device of claim 21, further comprising:
a capacitive touch printed circuit board affixed to the actuation member, the capacitive touch printed circuit board comprising one or more receiving capacitive touch pads located on the capacitive touch printed circuit board, and adjacent to a surface of the actuation member that is opposite the front surface, and arranged in a linear array adjacent to the touch sensitive surface;
wherein the control circuit is responsive to inputs received from the capacitive touch pads of the capacitive touch printed circuit board; and
wherein the capacitive touch printed circuit board is configured to pivot with the actuation member in response to actuation of the upper portion and the lower portion of the actuation member.

24. (canceled)

25. The control device of claim 1, wherein, when the motor load is on, the control circuit configured to determine fourth control data for adjusting the motor load to a maximum speed of the number of discrete speeds in response to an actuation of an upper portion of the actuation member.

26. The control device of claim 1, further comprising:
a motor load control circuit configured to conduct a load current through the motor load for controlling the rotational speed of the motor in response to the first, second, or third control data.

27. The control device of claim 1, further comprising:
a communication circuit configured to transmit a message including the first, second, or third control data, wherein the message is configured to cause a change in the rotational speed of the motor.

28. (canceled)

29. The control device of claim 1, wherein the touch sensitive surface is positioned along and proximate to the light bar.

30. The control device of claim 1, wherein the number of respective regions are along the light bar on the touch sensitive surface.

31. The control device of claim 1, wherein the control circuit is configured to control the rotational speed of the motor load to a plurality of discrete speeds, and the regions along the touch sensitive surface comprise a plurality of regions, each of the plurality of regions corresponding to a respective one of the plurality of discrete speeds.

32. The control device of claim 31, wherein the plurality of regions each comprise a respective length along the touch sensitive surface, and wherein a second region of the plurality of regions is located above a first region of the plurality of regions.

33. The control device of claim 32, wherein the length of the first region is shorter than the length of the second region.

34. The control device of claim 32, wherein a third region of the plurality of regions is located above the second region, and wherein the lengths of the second and third regions are equal to each other.

35. The control device of claim 32, wherein the light bar comprises a continuous light bar, and the control circuit is configured to illuminate a first portion of the light bar when the motor load is controlled to a first of the plurality of discrete speeds, and a second portion of the light bar when the motor load is controlled to a second of the plurality of discrete speed.

36. The control device of claim 35, wherein the first portion extends from the bottom end to a first point on the light bar, and the second portion extends from the bottom end to a second point on the light bar.

37. The control device of claim 36, wherein the plurality of regions each comprise a respective length along the touch sensitive surface, wherein a second region of the plurality of regions is located above a first region of the plurality of regions, and wherein the length of the first region is shorter than the length of the second region.

38. The control device of claim 37, wherein the first portion extends for a length equal to the length of the first region, and the second portion extends for a length equal to the lengths of the first and second regions.

39. The control device of claim 37, wherein the first portion extends into the second region.

40. The control device of claim 36, wherein lengths of first and second portions are equal.

41. The control device of claim 35, wherein the first portion extends from the bottom end to a first point on the light bar, and the second portion extends from the first point on the light bar to a second point on the light bar.

42. The control device of claim 41, wherein the first portion extends for a length equal to the length of the first region, and the second portion extends for a length equal to the length of second region.

43. The control device of claim 41, wherein the first portion extends into the second region.
